(19) United States
(12) Patent Application Publication
(10) Pub. No.: US 2026/0101599 A1
(43) Pub. Date: Apr. 9, 2026

(54) IMAGE SENSOR

(71) Applicant: SAMSUNG ELECTRONICS CO., LTD., Suwon-si (KR)

(72) Inventors: Gyeongjin LEE, Suwon-si (KR); HYUNGEUN YOO, Suwon-si (KR)

(73) Assignee: SAMSUNG ELECTRONICS CO., LTD., Suwon-si (KR)

(21) Appl. No.: 19/278,075

(22) Filed: Jul. 23, 2025

(30) Foreign Application Priority Data
Oct. 7, 2024 (KR) 10-2024-0136067

(51) Int. Cl. H10F 39/00; G02B 3/00; G02B 5/20; H10F 39/18

(52) U.S. Cl. CPC H10F 39/8063; G02B 3/0043; G02B 5/201; H10F 39/024; H10F 39/182; H10F 39/8053

(57) ABSTRACT

An image sensor is provided. The image sensor includes: a first color filter and a first microlens provided on first photoelectric conversion elements in a first region of a substrate; a second color filter and a second microlens provided on second photoelectric conversion elements in a second region of the substrate; and a third color filter and a third microlens provided on third photoelectric conversion elements in a third region of the substrate. The first microlens overlaps with a first photoelectric conversion element among the first photoelectric conversion elements. The second microlens overlaps with at least four of the second photoelectric conversion elements. A thickness of the second microlens is greater than a thickness of the first microlens.

### CROSS-REFERENCE TO RELATED APPLICATION

This application claims priority to Korean Patent Application No. 10-2024-0136067, filed in the Korean Intellectual Property Office, on Oct. 7, 2024, the disclosure of which is incorporated by reference herein in its entirety.

### BACKGROUND

### Field

The present disclosure relates to an image sensor.

### Related Art

An image sensor is a semiconductor device that converts optical images into electrical signals. Image sensors may be classified as, for example, a charge coupled device (CCD) type or a complementary metal oxide semiconductor (CMOS) type. The CMOS type image sensor may be referred to as a CMOS image sensor (CIS). The CIS includes a plurality of pixels arranged two-dimensionally, and each of the pixels includes a photodiode (PD), which converts incident light into an electrical signal.

A pixel may be divided into a positive electrode region that accepts light and a negative electrode region that does not accept light. A microlens may focus incoming light to the positive electrode region. This structure increases pixel sensitivity and reduces a pixel noise caused by a structure of a target object to be photographed.

### SUMMARY

One or more example embodiments provide an image sensor with improved AFC by forming different thicknesses for each lens.

According to an aspect of an example embodiment, an image sensor includes: a first substrate; a first color filter and a first microlens provided on a plurality of first photoelectric conversion elements in a first region of the first substrate; a second color filter and a second microlens provided on a plurality of second photoelectric conversion elements in a second region of the first substrate; and a third color filter and a third microlens provided on a plurality of third photoelectric conversion elements in a third region of the first substrate. The first microlens overlaps with a first photoelectric conversion element among the plurality of first photoelectric conversion elements. The second microlens overlaps with at least four of the plurality of second photoelectric conversion elements. A thickness of the second microlens is greater than a thickness of the first microlens.

According to another aspect of an example embodiment, an image sensor includes: a first substrate; a first color filter and a first microlens provided on a plurality of first photoelectric conversion elements in a first region of the first substrate; a second color filter and a second microlens provided on a plurality of second photoelectric conversion elements in a second region of the first substrate; and a third color filter and a third microlens provided on a plurality of third photoelectric conversion elements in a third region of the first substrate. A first quantity of the plurality of first photoelectric conversion elements overlapping with the first microlens, a second quantity of the plurality of second photoelectric conversion elements overlapping with the second microlens, and a third quantity of the plurality of third photoelectric conversion elements overlapping with the third microlens are the same. A thickness of the first microlens and a thickness of the third microlens are different.

According to another aspect of an example embodiment, an image sensor includes: a first substrate; a first color filter and a first microlens provided on a plurality of first photoelectric conversion elements in a first region of the first substrate; a second color filter and a second microlens provided on a plurality of second photoelectric conversion elements in a second region of the first substrate; and a third color filter and a third microlens provided on a plurality of third photoelectric conversion elements in a third region of the first substrate. A quantity of the plurality of second photoelectric conversion elements is at least two times greater than a quantity of the plurality of first photoelectric conversion elements. A thickness of the second microlens is greater than a thickness of the first microlens.

One or more example embodiments provide an image sensor with improved AFC by forming different thicknesses for each lens.

### BRIEF DESCRIPTION OF DRAWINGS

The above and other aspects and features will be more apparent from the following description of example embodiments with reference to the attached drawings, in which:

FIG. 1 is a block diagram of an image sensor according to an example embodiment.

FIG. 2 is a circuit diagram of one pixel included in an image sensor according to an example embodiment.

FIG. 3 schematically shows a planar view of an image sensor according to an example embodiment.

FIG. 4 is a cross-sectional view taken along lines II-II′ and III-III′ of FIG. 3.

FIG. 5 shows focal positions when a thickness of a microlens located in a green pixel area and a thickness of a microlens located in a red pixel area are the same.

FIG. 6 shows focal positions when a thickness of a microlens located in a green pixel area and a thickness of a microlens located in a red pixel area are different.

FIG. 7 to FIG. 13 show a manufacturing process of an image sensor according to an example embodiment.

FIG. 14 to FIG. 18 show a manufacturing process of an image sensor according to another example embodiment.

FIG. 19 shows a planar view of an image sensor according to an example embodiment.

FIG. 20 shows a cross-section taken from a cross-sectional of FIG. 19.

FIG. 21 to FIG. 51 show an image sensor according to various example embodiments.

FIG. 52 schematically shows a pixel array region according to an example embodiment.

FIG. 53 schematically shows a cross-section for a pixel located on an outer area according to an example embodiment.

FIG. 54 shows a cross-section for a pixel located on an outer area according to an example embodiment.

### DETAILED DESCRIPTION

Example embodiments will be described more fully hereinafter with reference to the accompanying drawings. As those skilled in the art would realize, example embodiments described herein may be modified in various different ways, all without departing from the spirit or scope of the present disclosure.

To clearly describe the present disclosure, parts that are irrelevant to the description are omitted, and like numerals refer to like or similar constituent elements throughout the specification.

Further, because sizes and thicknesses of constituent members shown in the accompanying drawings are given for better understanding and ease of description, the present disclosure is not limited to the illustrated sizes and thicknesses. In the drawings, the thicknesses of layers, films, panels, regions, areas, etc., may be exaggerated for clarity.

It will be understood that when an element such as a layer, film, region, or substrate is referred to as being “on” another element, it can be directly on the other element or intervening elements may also be present. In contrast, when an element is referred to as being “directly on” another element, there are no intervening elements present. Further, in the specification, the word “on” or “above” indicates located on or below the object portion, and does not necessarily indicate located on the upper side of the object portion based on a gravitational direction.

In addition, unless explicitly described to the contrary, the word “comprise” and variations such as “comprises” or “comprising” will be understood to imply the inclusion of stated elements but not the exclusion of any other elements.

Further, throughout the specification, the phrase “in a plan view” indicates when an object portion is viewed from above, and the phrase “in a cross-sectional view” indicates when a cross-section taken by vertically cutting an object portion is viewed from the side.

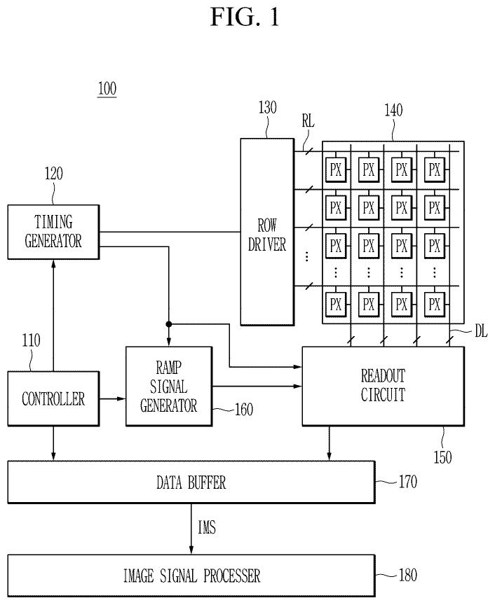

FIG. 1 is an example block diagram of an image sensor according to an example embodiment.

Referring to FIG. 1, an image sensor 100 according to an example embodiment may include a controller 110, a timing generator 120, a row driver 130, a pixel array 140, a readout circuit 150, a ramp signal generator 160, data buffer 170 and an image signal processor 180. In an example embodiment, the image signal processor 180 may be located outside the image sensor 100.

The image sensor 100 may generate an image signal by converting light received from outside into an electrical signal. The image signal IMS may be provided to the image signal processor 180.

The image sensor 100 may be mounted on an electronic device having an image or light sensing function. For example, the image sensor 100 may be mounted on an electronic device such as a camera, a smartphone, a wearable device, an Internet of things (IoT) devices, a home appliance, a tablet personal computer (PC), a personal digital assistant (PDA), a portable multimedia player (PMP), a navigation device, a drone, an advanced driver assistance system (ADAS), etc. Alternatively, the image sensor 100 may be mounted on an electronic device provided as a part of a vehicle, a furniture, a manufacturing facility, a door, or various measuring devices.

The controller 110 may generally control each of the components 120, 130, 150, 160, and 170 included in the image sensor 100. For example, the controller 110 may control an operation timing of each of the components 120, 130, 150, 160, and 170 by using control signals. In an example embodiment, the controller 110 may receive a mode signal indicating an imaging mode from an application processor, and may generally control the image sensor 100 based on the received mode signal. For example, the application processor may determine an imaging mode of the image sensor 100 according to various scenarios such as illumination of an imaging environment, resolution setting of a user, and a sensed or learned state, and may provide a determined result to the controller 110 as a mode signal. The controller 110 may control a plurality of pixels of the pixel array 140 to output pixel signals according to the imaging mode, the pixel array 140 may output a pixel signal for each of the pixels or a pixel signal for some of the pixels, and the readout circuit 150 may sample and process pixel signals received from the pixel array 140. The timing generator 120 may generate a signal that serves as a reference for operation timings of components of the image sensor 100. The timing generator 120 may control timings of the row driver 130, the readout circuit 150, and the ramp signal generator 160. The timing generator 120 may provide a control signal that controls the timings of the low driver 130, the readout circuit 150, and the ramp signal generator 160.

The pixel array 140 may include a plurality of pixels PX, and a plurality of row lines RL connected to the plurality of pixels PX, respectively, and a plurality of column lines DL. In an example embodiment, each of the pixels PX may include at least one photoelectric conversion element. The photoelectric conversion element may detect incident light, and may convert the incident light into an electrical signal according to an amount of light, i.e., a plurality of analog pixel signals. The photoelectric conversion element may be a photodiode, a pinned diode, or the like. Additionally, the photoelectric conversion element may be a single-photon avalanche diode (SPAD) applied to a 3D sensor pixel. A level of an analog pixel signal outputted from the photoelectric conversion element may be proportional to an amount of charge outputted from the photoelectric conversion element. That is, the level of the analog pixel signal output from the photoelectric conversion element may be determined according to an amount of light received into the pixel array 140.

The row lines RL may extend in a first direction, and may be connected to the pixels PX located along the first direction. For example, a control signal outputted from the row driver 130 to the row line RL may be transferred to gates of transistors of a plurality of pixels PX connected to the row line RL. The column lines DL may extend in a second direction crossing the first direction, and may be connected to the pixels PX located along the second direction. A plurality of pixel signals outputted from the pixels PX may be transferred to the readout circuit 150 through the column lines DL.

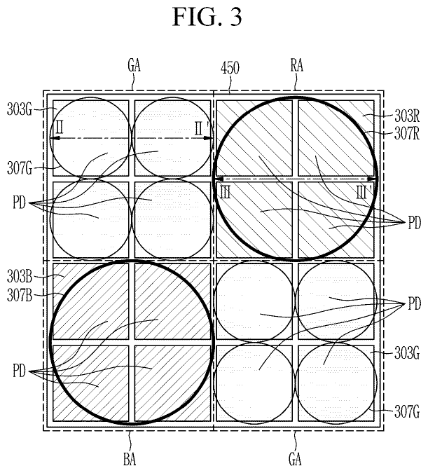

A color filter layer and a microlens layer may be located on the pixel array 140. The microlens layer includes a plurality of microlenses, and each of the microlenses may be located at an upper portion of the at least one corresponding pixel PX. The color filter layer may include the color filter of red, green, blue, or the like. For one pixel PX, a color filter of one color may be located between the pixel PX and the corresponding microlens. In a plan view, size and thickness of microlens corresponding to each pixels PX may be different. Detailed structure of the microlens will be hereinafter describe in detail with reference to FIG. 3.

The row driver 130 may generate a control signal for driving the pixel array 140 in response to a control signal of the timing generator 120, and control signals may be supplied to the pixels PX of the pixel array 140 through the row lines RL. In an example embodiment, the row driver 130 may control the pixels PX to sense light incident in a row line unit. The row line unit may include at least one row line RL. For example, the row driver 130 may provide a transfer signal TS, a reset signal RS, a selection signal SEL, etc., to the pixel array 140, as will be described later.

In response to the control signal from the timing generator 120, the readout circuit 150 may convert pixel signals (or electrical signals) from the pixels PX connected to the row line RL selected from among the pixels PX into pixel values representing an amount of light. The readout circuit 150 may convert the pixel signal outputted through the corresponding column line DL into a pixel value. For example, the readout circuit 150 may convert the pixel signal into the pixel value by comparing a ramp signal and the pixel signal. A pixel value may be image data having multiple bits. Specifically, the readout circuit 150 may include a selector, a plurality of comparators, a plurality of counter circuits, and the like.

The ramp signal generator 160 may generate and transmit a reference signal to the readout circuit 150.

The ramp signal generator 160 may include a current source, a resistor, and a capacitor. The ramp signal generator 160 may generate a plurality of ramp signals that fall or rise with a slope determined according to a current magnitude of a variable current source or a resistance value of a variable resistor by adjusting a ramp voltage. The ramp voltage is a voltage applied to ramp resistance, and is adjusted by adjusting the current magnitude of the variable current source or the resistance value of the variable resistor.

The data buffer 170 may store pixel values of the pixels PX connected to the selected column line DL transferred from the readout circuit 150, and may output the stored pixel values in response to an enable signal from the controller 110.

The image signal processor 180 may perform image signal processing on the image signal received from the data buffer 170. For example, the image signal processor 180 may receive a plurality of image signals from the data buffer 170, may and synthesize the received image signals to generate one image.

In an example embodiment, the pixels may be grouped in the form of M*N (M and N is an integer of 2 or more) to form one unit pixel group. The M*N form may be a form in which M items are arranged in an arrangement direction of the column lines DL and N items are arranged in an arrangement direction of the row lines RL. For example, one unit pixel group may include a plurality of pixels arranged in a 2*2 format, and one unit pixel group may output one analog pixel signal. The following example is not limited to one pixel, but may also be applied to a group of unit pixels.

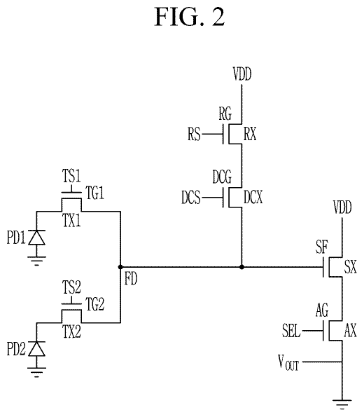

FIG. 2 is a circuit diagram of one pixel included in the image sensor according to an example embodiment.

Referring to FIG. 2, one pixel may include a plurality of photoelectric conversion elements PD1 and PD2. Each of the photoelectric conversion elements PD1 and PD2 may perform photoelectric conversion. As shown in FIG. 2, the photoelectric conversion elements PD1 and PD2 may be connected to one floating diffusion region FD. FIG. 2 illustrates a configuration in which two photoelectric conversion elements are connected to one floating diffusion region FD, but this is only an example, and a quantity of photoelectric conversion elements connected to one floating diffusion region FD may vary according to example embodiments.

Hereinafter, a description will focus on a first photoelectric conversion element PD1, but the following description equally applies to the other photoelectric conversion elements PD2.

The first photoelectric conversion element PD1 may generate and accumulate charge according to an amount of light received. The first photoelectric conversion element PD1 may include an anode connected to ground and a cathode connected to a first end of a first transmission transistor TX1. A first transmission signal TS1 may be supplied to a gate TG1 of the first transfer transmission TX1, and the first end of the first transmission transistor TX1 may be connected to the floating diffusion region FD. If the first transmission transistor TX1 is turned on by the first transmission signal TS1, charges accumulated in the first photoelectric conversion element PD1 may be transferred to the floating diffusion region FD. The floating diffusion region FD may maintain the charges transferred from the photoelectric conversion element PD.

Each of a plurality of transfer transistors TX1 and TX2 is connected between one of the photoelectric conversion elements PD1 and PD2 and the floating diffusion region FD, and may include gate electrodes TG1 and TG2 that receive a plurality of transmission signals TS1 and TS2. For example, the first transmission transistor TX1 may be connected between the first photoelectric conversion element PD1 and the floating diffusion area FD, and may include the gate electrode TG1 that receives the first transmission signal TS1. A quantity of the transmission transistors TX1 and TX2 may be equal to that of the photoelectric conversion elements PD1 and PD2.

The reset transistor RX may be connected between the power source voltage VDD and the floating diffusion area FD, and may include the gate electrode RG that receives a reset signal RS.

The reset transistor RX may periodically reset the charges accumulated in the floating diffusion region FD. A drain electrode of the reset transistor RX may be connected to a source electrode of a dual conversion transistor DCX, and the source electrode may be connected to a power source voltage VDD. If the reset transistor RX is turned on, the power source voltage VDD connected to the source electrode of the reset transistor RX may be applied to the floating diffusion region FD. Accordingly, if the reset transistor RX is turned on, the charges accumulated in the floating diffusion region FD may be discharged to reset the floating diffusion region FD.

The dual conversion transistor DCX may be located between the reset transistor RX and the floating diffusion region FD, and may include a gate electrode DCG that receives a dual conversion signal DCS. The dual conversion transistor DCX may reset the floating diffusion region FD together with the reset transistor RX. According to another example embodiment, the dual conversion transistor DCX may be omitted.

A drain electrode of the dual conversion transistor DCX may be connected to the floating diffusion region FD, and the source electrode of the dual conversion transistor DCX may be connected to the drain electrode of the reset transistor RX. If the reset transistor RX and the dual conversion transistor DCX are turned on, the power source voltage VDD connected to the source electrode of the reset transistor RX may be applied to the floating diffusion region FD through the dual conversion transistor DCX. Accordingly, the charges accumulated in the floating diffusion region FD may be discharged to reset the floating diffusion region FD.

An amplification transistor SX may output a pixel signal according to a voltage of the floating diffusion region FD. A gate SF of the amplifying transistor SX may be connected to the floating diffusion region FD, a power source voltage VDD may be supplied to a source electrode of the amplifying transistor SX, and a drain electrode of the amplifying transistor SX may be connected to a first end of a selection transistor AX. The amplifying transistor SX may constitute a source follower circuit, and may output a voltage of a level corresponding to the charges accumulated in the floating diffusion region FD as a pixel signal.

If the selection transistor AX is turned on by the selection signal SEL, the pixel signal from the amplification transistor SX may be transferred to the readout circuit. The selection signal SEL may be applied to the gate electrode AG of the selection transistor AX, and the drain electrode of the selection transistor AX may be connected to an output wire V_{OUT} that outputs a plurality of pixel signals.

An operation of the image sensor will be described with reference to FIG. 2 as follows. First, with light blocked, the power source voltage VDD is applied to the drain electrode of the reset transistor RX and the drain electrode of the amplification transistor SX. And the reset transistor RX and the dual conversion transistor DCX are turned on to discharge the remaining charges in the floating diffusion region FD. Thereafter, if the reset transistor RX is turned off and external light is incident on the photoelectric conversion elements PD1 and PD2, electron-hole pairs are generated in each of the photoelectric conversion elements PD1 and PD2. Holes move to p-type impurity regions of the photoelectric conversion elements PD1 and PD2, and electrons move to n-type impurity regions to be accumulated. If the transmission transistors TX1 and TX2 are turned on, charges such as electrons and holes are transferred to the floating diffusion region FD to be accumulated. A gate bias of the amplification transistor SX changes in proportion to the accumulated charges, which causes a change in the source potential of the amplification transistor SX. In this case, if the selection transistor AX is turned on, a signal by charges is read through the output wire V_{OUT}.

A wire may be electrically connected to at least one of the gate electrodes TG1 and TG2 of transmission transistors TX1 and TX2, the gate electrodes SF of the amplification transistor SX, the gate electrode DCG of the dual conversion transistor DCX, the gate electrode RG of the reset transistor RX, or the gate electrode AG of the select transistor AX. The wire may include a power source voltage transmission wire that applies the power source voltage VDD to the source electrode of the reset transistor RX or the source electrode of the amplification transistor SX. The wire may include an output wire V_{OUT} connected to the selection transistor AX.

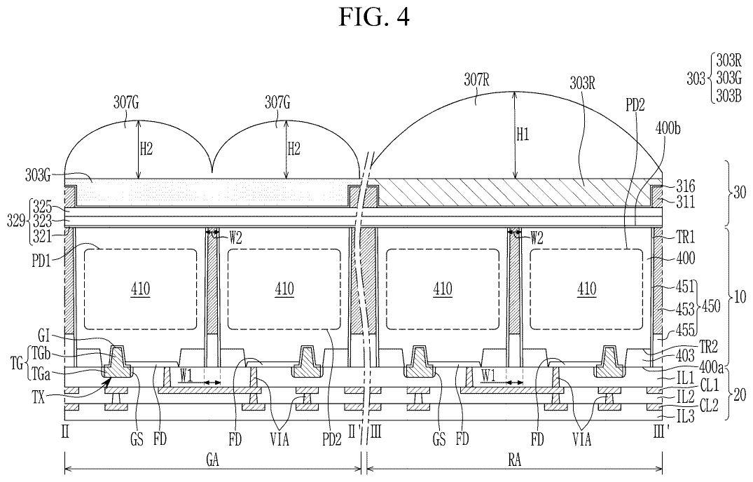

FIG. 3 schematically shows a planar view of the image sensor according to an example embodiment. FIG. 4 is a cross-sectional view taken along lines II-II′ and III-III′ of FIG. 3.

However, plan and cross sections of FIG. 3 and FIG. 4 are example cross sections for convenience of description, but example embodiments are not limited thereto.

Referring to FIG. 3, the image sensor may include a plurality of photoelectric conversion elements PD and the color filters 303R, 303G, and 303B located on the plurality of photoelectric conversion elements PD. A region where a red color filter 330R is located may be a red pixel area RA, a region where a green color filter 330G is located may be a green pixel area GA, and a region where a blue color filter 330B is located may be a blue pixel area BA. Microlenses 307R, 307G, and 307B may be located on the color filters. At this time, the arrangement form of the microlens may be different from region to region. As shown in FIG. 3, in the green pixel area GA, one microlens 307G may be located on one photoelectric conversion element PD, and in the red pixel area RA, one microlens 307R may be located on four photoelectric conversion elements PD. In the same way, in the blue pixel area BA, one microlens 307B may be located on the four photoelectric conversion elements PD. Because the planar size of the microlens 307 located in respective pixel area is different, if the thickness of the microlens 307 in each pixel area is made the same, the focus can be formed in a different position for each pixel. One or more example embodiments allow the focal position to be adjusted by varying the thickness of the microlens depending on the pixel area and the size of the microlens. In FIG. 3, microlenses with thicknesses that are greater than those of neighboring microlenses are depicted by bold lines. That is, in FIG. 3, a thickness of the microlens 307R located in the red pixel area RA and a thickness of the microlens 307B located in the blue pixel area BA may be greater than a thickness of the microlens 307G located in the green pixel areas GA. When a microlens 307 is drawn with a bold line in the drawings included in this specification, it indicates that it is thicker than a microlens 307 that is not drawn with a bold line. The thickness of the microlens 307 in this specification may indicate a thickness of a thickest portion of the microlens 307.

In FIG. 3, a pixel separation pattern 450 is illustrated between each photoelectric conversion element PD. In FIG. 3, the pixel separation pattern 450 is illustrated as completely separating each photoelectric conversion element PD, but this is merely an example, and the pixel separation pattern 450 may include a separation area without completely separating the photoelectric conversion elements PD. For example, the plurality of photoelectric conversion elements PD located in pixel areas RA, GA, and BA, respectively, may be connected to each other to be integral with each other.

Referring to FIG. 3 and FIG. 4, the image sensor may include a photoelectric conversion layer 10, a gate electrode TG of a transfer transistor, a first wiring region 20, and a light transmission layer 30. The photoelectric conversion layer 10 may include a first substrate 400 and a pixel separation pattern 450. The gate electrode AG of the selection transistor AX may be located on a same layer as the gate electrode RG of the reset transistor RX, the gate electrode DCG of the dual conversion transistor DCX, the gate electrode SF of the amplification transistor SX, and the gate electrode TG of the transfer transistor. However, this is merely an example, and according to an example embodiment, the gate electrode RG of the reset transistor RX, the gate electrode DCG of the dual conversion transistor DCX, the gate electrode SF of the amplification transistor SX, and the gate electrode AG of the selection transistor AX may be electrically connected to each other while being located on a different substrate from the gate electrode TG of the transfer transistor.

Referring to FIG. 4, the first substrate 400 may include a first surface 400a and a second surface 400b opposite each other. Light may be incident on the second surface 400b of the first substrate 400. The first wiring region 20 may be located on the first surface 400a of the first substrate 400, and the light transmission layer 30 may be located on the second surface 400b of the first substrate 400. The first substrate 400 may be a semiconductor substrate or a silicon on insulator (SOI) substrate. For example, the semiconductor substrate may include a silicon substrate, a germanium substrate, or a silicon-germanium substrate. The first substrate 400 may include impurities of a first conductivity type. For example, the impurities of the first conductivity type may be p-type impurities such as aluminum (Al), boron (B), indium (In) and/or gallium (Ga).

The photoelectric conversion region 410 may perform the same function and role as those of the photoelectric conversion elements PD1 and PD2 illustrated in FIG. 2.

The photoelectric conversion region 410 may be a region doped with impurities of a second conductivity type in the first substrate 400. The impurities of the second conductivity type may have a conductivity type opposite to that of the impurities of the first conductivity type. The impurities of the second conductivity type may include n-type impurities such as phosphorus, arsenic, bismuth, and/or antimony. For example, each photoelectric conversion region 410 may include a first region adjacent to the first surface 400a and a second region adjacent to the second surface 400b. There may be a difference in impurity concentration between the first region and the second region of the photoelectric conversion region 410. Accordingly, the photoelectric conversion region 410 may have a potential slope between the first surface 400a and the second surface 400b of the first substrate 400. As another example, the photoelectric conversion region 410 may not have a potential slope between the first surface 400a and the second surface 400b of the first substrate 400.

The first substrate 400 and the photoelectric conversion region 410 may constitute a photodiode. That is, the photodiode may be formed by a p-n junction between the first substrate 400 of the first conductivity type and the photoelectric conversion region 410 of the second conductivity type. The photoelectric conversion region 410 constituting the photodiode may generate and accumulate photocharges in proportion to intensity of incident light.

Referring to FIG. 3 and FIG. 4, a pixel separation pattern 450 may be located in the first substrate 400. The pixel separation pattern 450 may have a grid structure and may partition each pixel in a plan view.

Referring to FIG. 4, the pixel separation pattern 450 may be disposed in a first trench TR1. The first trench TR1 may be recessed from the first surface 400a of the first substrate 400. The pixel separation pattern 450 may extend from the first surface 400a of the first substrate 400 toward the second surface 400b. The pixel separation pattern 450 may be a deep trench isolation (DTI) film. The pixel separation pattern 450 may extend through the first substrate 400. A vertical height of the pixel separation pattern 450 may be substantially the same as a vertical thickness of the first substrate 400. For example, a width of the pixel separation pattern 450 may gradually decrease from the first surface 400a to the second surface 400b of the first substrate 400.

The pixel separation pattern 450 may include a first separation pattern 451, a second separation pattern 453, and a capping pattern 455. The first separation pattern 451 may be located along a sidewall of the first trench TR1. The first separation pattern 451 may include, e.g., a silicon-based insulating material (e.g., a silicon nitride, a silicon oxide, or a silicon oxynitride) or a high dielectric material (e.g., a hafnium oxide or an aluminum oxide). As another example, the first separation pattern 451 includes a plurality of layers, and the layers may include different materials. The first separation pattern 451 may have a lower refractive index than that of the first substrate 400. Accordingly, crosstalk between pixels PX positioned on the first substrate 400 may be prevented or reduced.

The second separation pattern 453 may be located within the first separation pattern 451. For example, a sidewall of the second separation pattern 453 may be surrounded by the first separation pattern 451. The first separation pattern 451 may be located between the second separation pattern 453 and the first substrate 400. The second separation pattern 453 may be separated from the first substrate 400 by the first separation pattern 451. Accordingly, if the image sensor operates, the second separation pattern 453 may be electrically separated from the first substrate 400. The second separation pattern 453 may include a crystalline semiconductor material, e.g., polycrystalline silicon. As an example, the second separation pattern 453 may further include a dopant, and the dopant may include impurities of the first conductivity type or impurities of the second conductivity type.

For example, the second separation pattern 453 may include doped polycrystalline silicon. Alternatively, the second separation pattern 453 may include an undoped crystalline semiconductor material. For example, the second separation pattern 453 may include undoped polycrystalline silicon. The term “undoped” may indicate that no intentional doping process has been performed. The dopant may include an n-type dopant and a p-type dopant.

The capping pattern 455 may be located on a lower surface of the second separation pattern 453. The capping pattern 455 may be located adjacent to the first surface 400a of the first substrate 400. The capping pattern 455 may include a non-conductive material. As an example, the capping pattern 455 may include, e.g., a silicon-based insulating material (e.g., a silicon nitride, a silicon oxide, or a silicon oxynitride) or a high dielectric material (e.g., a hafnium oxide or an aluminum oxide). Accordingly, the pixel separation pattern 450 may prevent photocharges generated by incident light incident on the pixels PX from being incident on another adjacent pixel PX due to random drift. That is, the pixel separation pattern 450 may prevent crosstalk between the pixels PX.

A device separation pattern 403 may be disposed within the first substrate 400. For example, the device separation pattern 403 may be located within a second trench TR2. The second trench TR2 may be recessed from the first surface 400a of the first substrate 400. The device separation pattern 403 may be a shallow trench isolation (STI) film. The device separation pattern 403 may define an activation pattern. An upper surface of the device separation pattern 403 may be located within the first substrate 400. A width of the device separation pattern 403 may gradually decrease from the first surface 400a to the second surface 400b of the first substrate 400. The upper surface of the device separation pattern 403 may be vertically spaced apart from the photoelectric conversion region 410. The device separation pattern 403 may include the same material as the first separation pattern 451 of the pixel separation pattern 450, and in this case, the boundary between the device separation pattern 403 and the first separation pattern 451 may not be visually recognized. However, this is only an example, and example embodiments are not limited thereto.

FIG. 4 shows a configuration in which the device separation pattern 403, the pixel separation pattern 450, and the first surface 400a of the first substrate 400 are positioned on the same plane, but this is only an example, and example embodiments are not limited thereto. For example, the device separation pattern 403, the pixel separation pattern 450, and the first surface 400a of the first substrate 400 may not be coplanar. The device separation pattern 403 and the pixel separation pattern 450 may protrude from or be recessed from the first surface 400a of the first substrate 400.

In addition, the upper surface of the device separation pattern 403 and the upper surface of the pixel separation pattern 450 are flat, but this is an example, and the upper surface of the device separation pattern 403 and the upper surface of the pixel separation pattern 450 may include curved surfaces.

The amplification transistor SX and the selection transistor AX may also be located on the first surface 400a of the first substrate 400. That is, the gate electrode SF of the amplification transistor SX and the gate electrode AG of the selection transistor AX may be located on the first surface 400a of the first substrate 400. In addition, the reset transistor RX and the dual conversion transistor DCX may be located on the first surface 400a of the first substrate 400. The reset transistor RX may include the reset gate RG, and the dual conversion transistor DCX may include the dual conversion gate DCG.

A gate dielectric film GI may be located between each of the transmission gate TG, the selection gate AG, the amplification gate SG, the dual conversion gate DCG, and the reset gate RG and the first substrate 400. A gate spacer GS may be located on a sidewall of each of the gate electrodes TG, AG, SG, DCG, and RG. The gate spacer GS may include, e.g., a silicon nitride, a silicon carbonitride, or a silicon oxynitride.

However, in another example embodiment, the image sensor may further include an opposing substrate that overlaps the first substrate 400, and one or more of the amplifying transistor SX, the selection transistor AX, the reset transistor RX, and the dual conversion transistor DCX may be located on an opposing substrate. In example embodiments, at least one of the amplification transistor SX, the selection transistor AX, the reset transistor RX, and the dual conversion transistor DCX positioned on the opposed substrate and the transmission transistor TX positioned on the first substrate 400 may be connected by a connection node.

The first wiring region 20 may be located on the first surface 400a of the first substrate 400, and may include a plurality of insulating layers IL1, IL2, and IL3, a plurality of wiring layers CL1 and CL2, and the via VIA.

The insulating layer may include a first insulating layer IL1, a second insulating layer IL2, and a third insulating layer IL3.

The first insulating layer IL1 may cover the first surface 400a of the first substrate 400. The first insulating layer IL1 may cover the gate electrode TG. The second insulating layer IL2 may be located on the first insulating layer IL1. The third insulating layer IL3 may be located on the second insulating layer IL2.

The first to third insulating layers IL1, IL2, and IL3 may each include a non-conductive material. For example, the first to third insulating layers IL1, IL2, and IL3 may each include a silicon-based insulating material such as a silicon oxide, a silicon nitride, or a silicon oxynitride.

The first wiring region 20 may include a first wiring layer CL1 and a second wiring layer CL2. The first wiring layer CL1 may be located within the second insulating layer IL2. The second wiring layer CL2 may be located within the third insulating layer IL3.

A plurality of vias VIA may be located in the first insulating layer IL1, the second insulating layer IL2, and the third insulating layer IL3. The vias VIA may connect the floating diffusion region FD, the first wiring layer CL1, and the second wiring layer CL2 to each other.

The first wiring layer CL1, the second wiring layer CL2, and the vias VIA may each include a metal material. As an example, the first wiring layer CL1, the second wiring layer CL2, and the vias VIA may each include copper (Cu).

The light transmission layer 30 may include an insulating structure 329, a color filter 303, and a microlens 307. The light transmission layer 30 may collect and filter light incident from the outside, and provide the light to the photoelectric conversion region 410.

The color filter 303 may be located on the second surface 400b of the first substrate 400. The color filters 303 may each be located in one pixel PX. The color filter 303 in each pixel PX may include primary color i.e., red, green and blue) filters. Referring to FIG. 3 and FIG. 4, the color filter 303 may include a red color filter 303R, a green color filter 303G, and a blue color filter 303B, which have different colors.

In FIG. 3, the red pixel area RA, the green pixel area GA, the blue pixel area BA are illustrated respectively. The red color filter 330R may be located to overlap with the red pixel area RA, the green color filter 330G may be located to overlap with the green pixel area GA, and the blue color filter 330B may be located to overlap with the blue pixel area BA. The red color filter 303R, the green color filter 303G, and the blue color filter 303B may be arranged in a Bayer pattern. Various arrangement forms of red color filters 303R, green color filters 303G, and blue color filters 303B will be described later. In this specification, an overlap includes not only a configuration in which a pixel area and a color filter completely overlap, but also a configuration in which they overlap in a shifted state considering the incident light.

Referring again to FIG. 4, an insulating structure 329 may be located between the second surface 400b of the first substrate 400 and the color filter 303. The insulating structure 329 may prevent reflection of light such that light incident on the second surface 400b of the first substrate 400 may smoothly reach the photoelectric conversion region 410. The insulating structure 329 may be referred to as an anti-reflection structure.

The insulating structure 329 includes a first fixed charge film 321, a second fixed charge film 323, and a planarization film 325 sequentially stacked on the second surface 400b of the first substrate 400.

The first fixed charge film 321, the second fixed charge film 323, and the planarization film 325 may include different materials. The first fixed charge film 321 may include any one of an aluminum oxide, a tantalum oxide, a titanium oxide, and a hafnium oxide. The second fixed charge film 323 may include any one of an aluminum oxide, a tantalum oxide, titanium oxide, and a hafnium oxide. For example, the first fixed charge film 321 may include an aluminum oxide, the second fixed charge film 323 may include a hafnium oxide, and the planarization film 325 may include a silicon oxide. In another example embodiment, a silicon anti-reflection layer may be interposed between the second fixed charge film 323 and the planarization film 325. The anti-reflection film may include a silicon nitride.

The light transmission layer 30 may further include a Bayer pattern 311 and a passivation layer 316. The Bayer patterns 311 may be located between the color filters 303 adjacent to each other to separate them from each other. The Bayer pattern 311 may be located on the insulation structure 329. For example, the Bayer pattern 311 may have a grid structure. The Bayer pattern 311 may include a material having a lower refractive index than the color filter 303. The Bayer pattern 311 may include an organic material. For example, the Bayer pattern 311 may be a polymer layer including silica nanoparticles. Because the Bayer pattern 311 has a low refractive index, the amount of light incident on the photoelectric conversion region 410 may be increased, and crosstalk between pixels PX may be reduced. That is, light receiving efficiency may be increased in each photoelectric conversion region 410, and a signal noise ratio (SNR) characteristic may be improved.

The passivation layer 316 may cover the surface of the Bayer pattern 311 with a substantially uniform thickness. The protective layer 316 may include, e.g., a single film or a multi-film of at least one of an aluminum oxide film or a silicon carbide oxide film. The protective layer 316 may protect the color filter 303, and may include a moisture absorbent material.

A microlens 307 may be located on the color filter 303. The microlens 307 may have a convex shape to focus light incident on the pixel PX. Each microlens 307 may vertically overlap the photoelectric conversion region 410. However, as will be explained separately later, in some regions, a center of the microlens 307 may not vertically overlap with a center of the photoelectric conversion region 410. That is, the center of the microlens 307 may not coincide with the center of the photoelectric conversion region 410, but may be shifted. For example, the center of the microlens 307 may be offset from the center of the photoelectric conversion region 410. In this regard, overlapping includes a case where the center of the microlens 07 does not coincide with the center of the photoelectric conversion region 410 but is shifted.

Referring to FIG. 4, a thickness H2 of the microlens 307G located in the green pixel area GA overlapping with the green color filter 330G and a thickness H1 of the microlens 307R located in the red pixel area RA overlapping with the red color filter 330R may be different. In this specification, the thickness of the microlens may indicate a thickness of a thickest portion of the microlens. As shown in FIG. 4, the microlens may have a shape in which the center is thickest and the thickness becomes thinner toward the edge, and at this time, as shown in FIG. 4, the thickness of the microlens may refer to the thickness of the central portion.

As shown in FIG. 4, the thickness H1 of the microlens 307R located in the red pixel area RA may be greater than the thickness H2 of the microlens 307G located in the green pixel area GA. This is because the sizes of the microlens 307G located in the green pixel area GA and the microlens 307R located in the red pixel area RA are different, as shown in FIG. 3 and FIG. 4. That is, because the sizes of the microlens 307G located in the green pixel area GA and the microlens 307R located in the red pixel area RA in a plan view are different, if respective microlenses 307G and 307R have the same thickness, the focal position of the light having passed through the microlens 307 may be different.

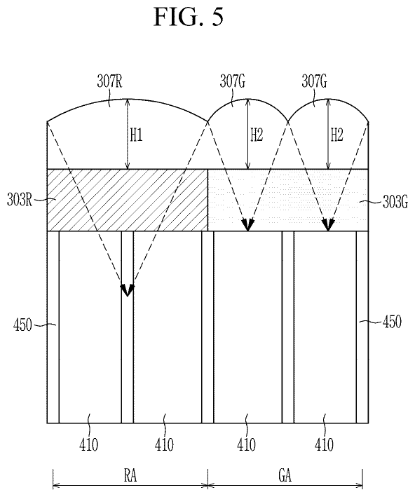

FIG. 5 illustrates focal positions when the thickness H2 of the microlens 307G located in the green pixel area GA and the thickness H1 of the microlens 307R located in the red pixel area RA are the same. For better understanding and ease of description, FIG. 5 schematically illustrates only some components. As shown in FIG. 5, when the thickness H2 of the microlens 307G located in the green pixel area GA and the thickness H1 of the microlens 307R located in the red pixel area RA are the same, the focus of the light having passed through the microlens 307G located in the green pixel area GA and the focal position of the light having passed through the microlens 307R located in the red pixel area RA may become different. This is because the sizes of respective microlenses 307R and 307G in a plan view are different.

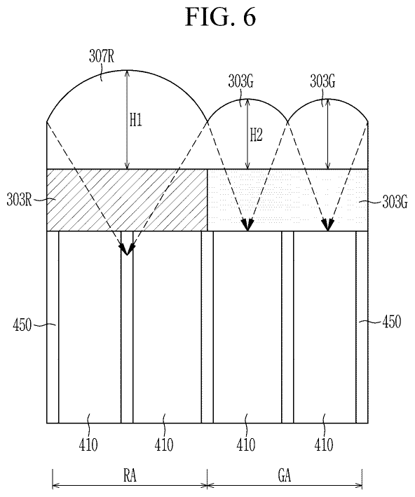

FIG. 6 illustrates focal positions when the thickness H2 of the microlens 307G located in the green pixel area GA and the thickness H1 of the microlens 307R located in the red pixel area RA are different. Referring to FIG. 6, in the image sensor according to an example embodiment, the thickness H1 of the microlens 307R located in the red pixel area RA is greater than the thickness H2 of the microlens 307G located in the green pixel area GA. When comparing FIG. 6 and FIG. 5, in the case of FIG. 6, because the thickness H1 of the microlens 307R located in the red pixel area RA is greater than the thickness H2 of the microlens 307G located in the green pixel area GA, in comparison with FIG. 5, the focus of the light having passed through the microlens 307R located in the red pixel area RA may be formed higher than in FIG. 5. Accordingly, referring to FIG. 6, the difference between the focus of the light having passed through the microlens 307G located in the green pixel area GA and the focal position of the light having passed through the microlens 307R located in the red pixel area RA may decrease than in FIG. 5. FIG. 6 illustrates that the focus of the light having passed through the microlens 307G located in the green pixel area GA and the focal position of the light having passed through the microlens 307R located in the red pixel area RA are different, but by adjusting the thickness of the microlens 307R located in the red pixel area RA, the focus of the light having passed through the microlens 307G located in the green pixel area GA and the focus of the light having passed through the microlens 307R located in the red pixel area RA may be made to stay on the same axis.

A manufacturing method of the microlenses 307R, 307G, and 307B of such shapes will be hereinafter be described. However, the manufacturing method below is an example, and example embodiments are not limited thereto.

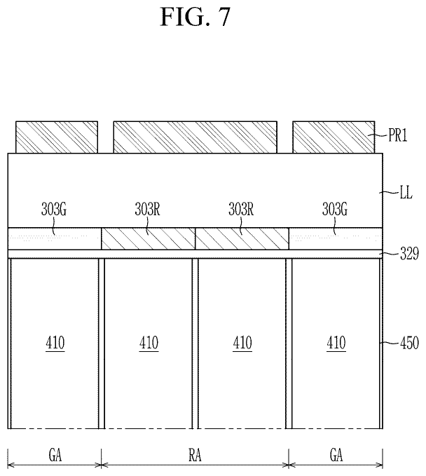

FIG. 7 to FIG. 13 show a manufacturing process of the image sensor according to an example embodiment. For better understanding and ease of description, some components of the image sensor are schematically illustrated. Referring to FIG. 7, the pixel separation pattern 450 may be located between each photoelectric conversion region 410. The green color filter 303G and the red color filter 303R may be located on the photoelectric conversion region 410, respectively. For better understanding and ease of description, FIG. 7 to FIG. 13 illustrate a configuration of the red color filter 303R overlapping with two photoelectric conversion regions 410 and the green color filter 303G located on both sides of the red color filter 303R, but such a configuration is merely an example, and example embodiments are not limited thereto. The insulation structure 329 may be located between the color filters 303G and 303R and the photoelectric conversion region 410. The description on the insulation structure 329 is the same as described above in FIG. 4.

Referring to FIG. 7, a lens layer LL may be formed on the color filter 303. In an example embodiment, the lens layer LL may include a polymer, and for example, the lens layer LL may be formed by a spin coating process using an organic material such as a photoresist material, or a thermosetting resin.

A first photoresist layer PR1 may be formed on the lens layer LL. The first photoresist layer PR1 may be formed to correspond to respective pixel areas GA and RA. Respective patterns of the first photoresist layer PR1 may be formed to have a gap with each other.

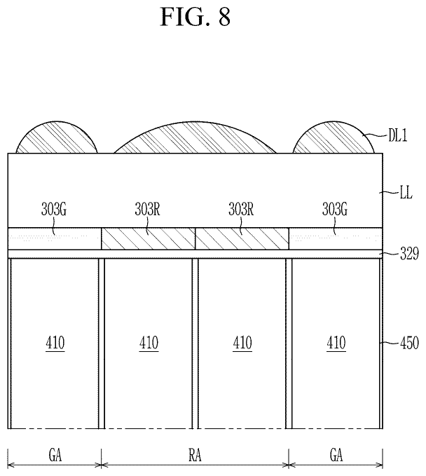

Referring to FIG. 8, a reflow process with respect to the first photoresist layer PR1 may be performed, and as a shape of the first photoresist layer PR1 changes, first dummy lenses DL1 having a convex hemisphere shape may be formed.

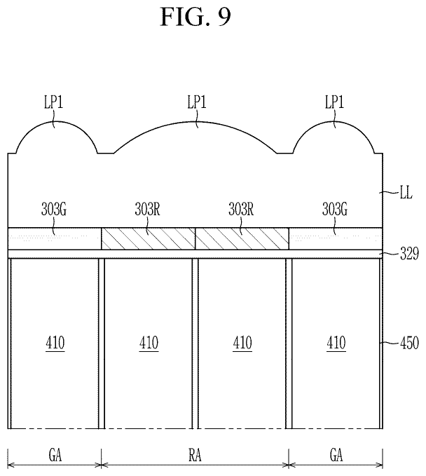

Referring to FIG. 9, through the etching process using the first dummy lenses DL1 as the etching mask, a portion of the lens layer LL may be etched, and a first microlens pattern LP1 may be formed. The first microlens pattern LP1 may be formed in the lens layer LL through a transfer etching process using the first dummy lenses DL1, and may be formed through the wet etch-back process using the first dummy lenses DL1 as the etching mask. The wet etching process may be performed using an etching chemical that does not cause damage to the color filter 303.

As the etching process is performed such that the shape of the first dummy lenses DL1 may be transferred to the lens layer LL, the first microlens pattern LP1 may be formed in a convex lens shape. The etching of the lens layer LL for forming the first microlens pattern LP1 may be performed until the photoresist forming the first dummy lenses DL1 is completely etched.

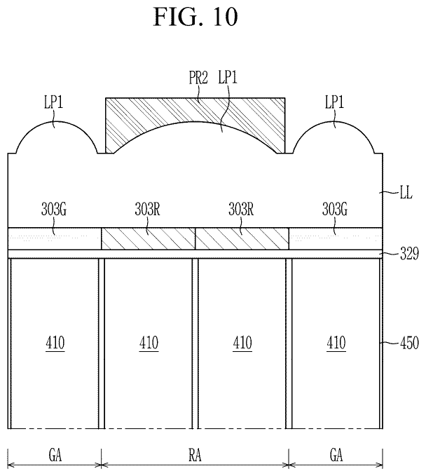

Referring to FIG. 10, a second photoresist layer PR2 may be formed on the first microlens pattern LP1. The second photoresist layer PR2 may be formed on the red pixel area RA as one common pattern.

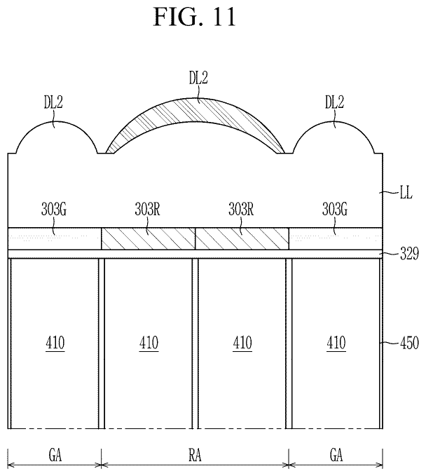

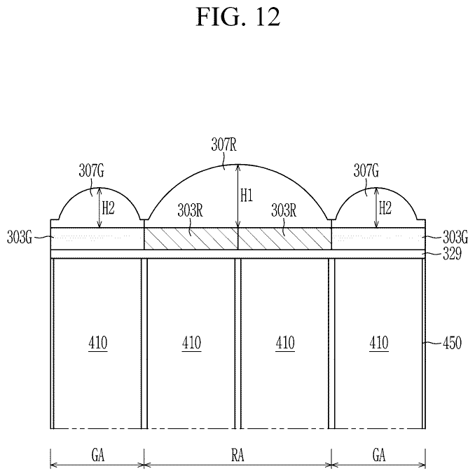

Referring to FIG. 11, a reflow process with respect to the second photoresist layer PR2 may be performed, and as a shape of the second photoresist layer PR2 changes, second dummy lenses DL2 having a convex hemisphere shape may be formed. Referring to FIG. 12, through the etching process using the second dummy lenses DL2 as the etching mask, a portion of the first microlens pattern LP1 may be etched, and the microlenses 307G and 307R may be formed. At this time, the microlenses 307G and 307R may be formed through the transfer etching process using the second dummy lenses DL2, through the wet etch-back process using the second dummy lenses DL2 as the etching mask.

As the etching process is performed, the shape of the second dummy lenses DL2 may be transferred to the first microlens pattern LP1, the thickness H1 of the microlens 307R located in the red pixel area RA may be formed to be greater than the thickness H2 of the microlens 307G located in the green pixel area GA. In this regard, the microlens 307R may extend higher (i.e., farther from the photoelectric conversion region 410) than the microlens 307G.

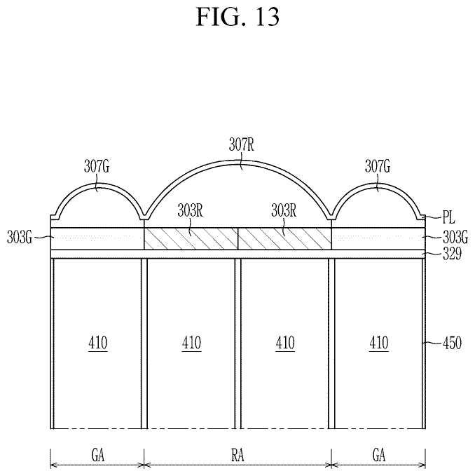

Referring to FIG. 13, an upper layer PL may be deposited on the microlenses 307G and 307R. For example, the upper layer PL may include an oxide.

As such, the microlenses 307R and 307G having different thicknesses may be formed by using the first photoresist layer PR1 and the second photoresist layer PR2. FIG. 7 to FIG. 13 describes a manufacturing process of etching by using the first photoresist layer PR1 and then etching by using the second photoresist layer PR2, but this is merely an example, and example embodiments are not limited thereto.

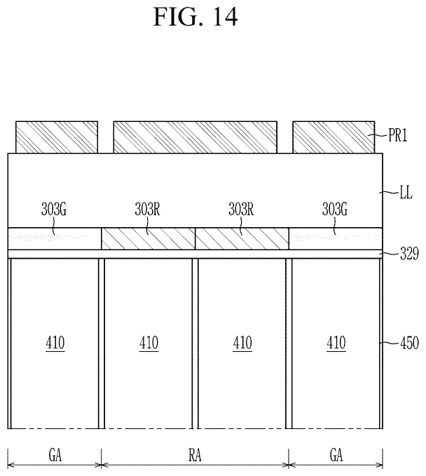

FIG. 14 to FIG. 18 show a manufacturing process of the image sensor according to another example embodiment. Referring to FIG. 14, the pixel separation pattern 450 may be located between each photoelectric conversion region 410. The green color filter 303G and the red color filter 303R may be located on the photoelectric conversion region 410, respectively. The insulation structure 329 may be located between the color filters 303G and 303R and the photoelectric conversion region 410. The description on the insulation structure 329 is the same as described above.

Referring to FIG. 14, the lens layer LL may be formed on the color filter 303. In an example embodiment, the lens layer LL may include a polymer, and for example, the lens layer LL may be formed by a spin coating process using an organic material such as a photoresist material, or thermosetting resin.

The first photoresist layer PR1 may be formed on the lens layer LL. The first photoresist layer PR1 may be formed to correspond to respective pixel areas GA and RA. Respective patterns of the first photoresist layer PR1 may be formed to have a gap with each other.

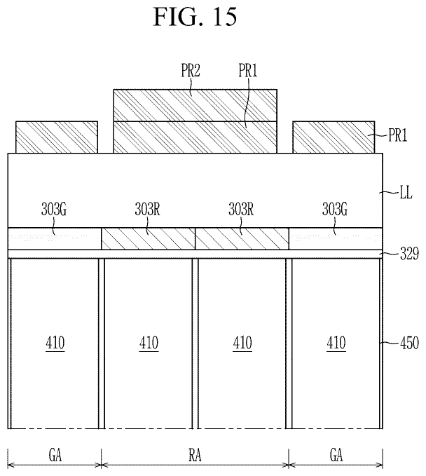

Referring to FIG. 15, the second photoresist layer PR2 may be formed on the first photoresist layer PR1. At this time, the second photoresist layer PR2 may be formed on the red pixel area RA as one common pattern. For example, the second photoresist layer PR2 may not be formed on the green pixel areas GA.

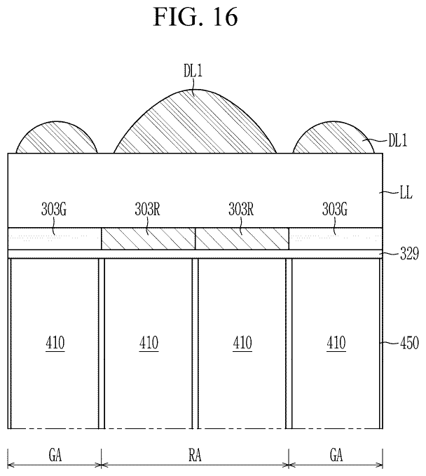

Referring to FIG. 16, the reflow process with respect to the first photoresist layer PR1 and the second photoresist layer PR2 may be performed, and as the shape of the first photoresist layer PR1 and the second photoresist layer PR2 changes, the first dummy lenses DL1 having a convex hemisphere shape may be formed. As shown, the first dummy lens DL1 corresponding to the red pixel area RA may be thicker than the first dummy lenses DL1 corresponding to the green pixel areas GA.

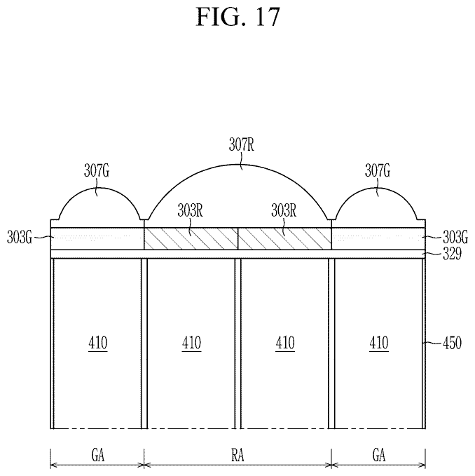

Referring to FIG. 17, through the etching process using the first dummy lenses DL1 as the etching mask, a portion of the lens layer LL may be etched such that the microlenses 307R and 307G may be formed such that the microlens 307R is thicker than the microlenses 307G.

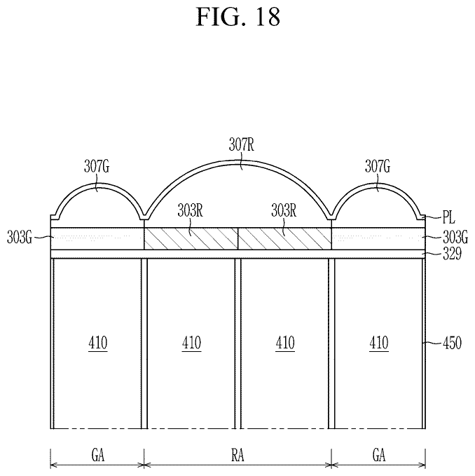

Referring to FIG. 18, the upper layer PL may be deposited on the microlenses 307G and 307R. For example, the upper layer PL may include an oxide.

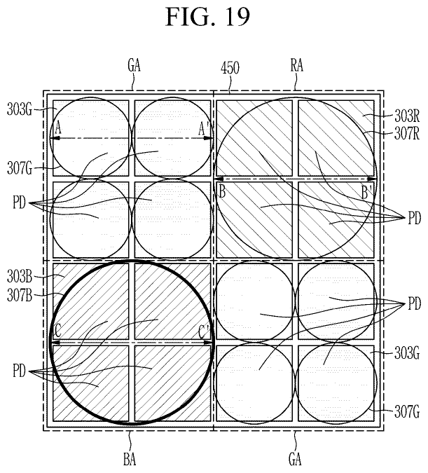

Image sensors according to various example embodiments will be hereinafter described. FIG. 19 shows a planar view of an image sensor according to an example embodiment. For example, the planar view of FIG. 19 may be the same region shown in FIG. 3. Referring to FIG. 19, the image sensor is the same as FIG. 3 except that the microlens 307B located in the blue pixel area BA is thicker than the microlenses 307G and the microlenses 307R. For example, the microlens 307R and the microlenses 307G may have the same thickness.

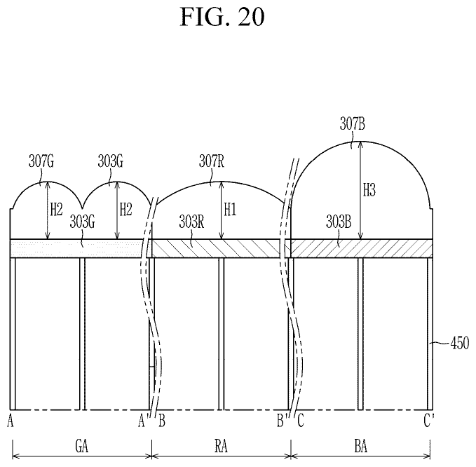

FIG. 20 shows cross-sectional views taken along lines A-A′, B-B′ and C-C′ of FIG. 19. For better understanding and ease of description, FIG. 20 briefly illustrates only some components. Referring to FIG. 20, the thickness H1 of the microlens 307R located in the red pixel area RA may be the same as the thickness H2 of the microlens 307G located in the green pixel area GA, and a thickness H3 of the microlens 307B located in the blue pixel area BA may be greater than the thickness H2. As such, the thickness of the microlens may be different only in some pixel areas.

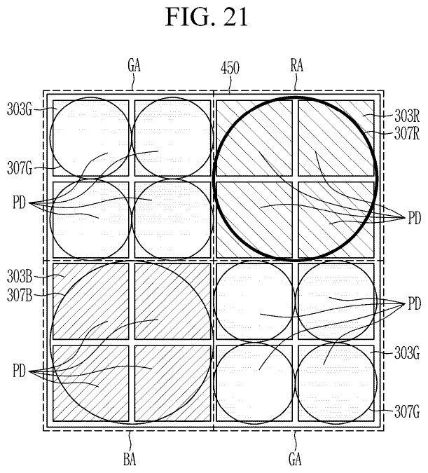

FIG. 21 shows a planar view of an image sensor according to an example embodiment. For example, the planar view of FIG. 21 may be the same region shown in FIG. 3. Referring to FIG. 21, the image sensor is the same as FIG. 3 except that the thickness of the microlens 307R located in the red pixel area RA is thicker than the microlenses 307G and the microlens 307B. That is, in FIG. 21, the thickness of the microlens 307B located in the blue pixel area BA and the thickness of the microlens 307G located in the green pixel area GA may be the same, and the thickness of the microlens 307R located in the red pixel area RA may be greater than each of the thicknesses of the microlens 307B and the thickness of the microlens 307G.

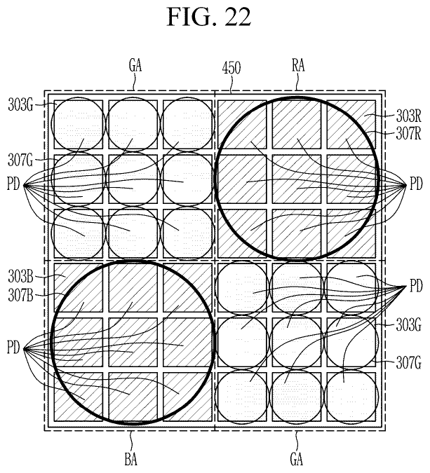

FIG. 22 shows a planar view of an image sensor according to an example embodiment. For example, the planar view of FIG. 22 may be the same region as FIG. 3. Referring to FIG. 22, the image sensor is the same as FIG. 3 except that each pixel area includes nine photoelectric conversion elements PD. Referring to FIG. 22, the green pixel area GA may include nine microlenses 307G, the red pixel area RA may include the one microlens 307R, and the blue pixel area BA may include the one microlens 307B. At this time, the thickness of the microlens 307B located in the blue pixel area BA and the thickness of the microlens 307R located in the red pixel area RA may be greater than the thickness of the microlens 307G located in the green pixel area GA.

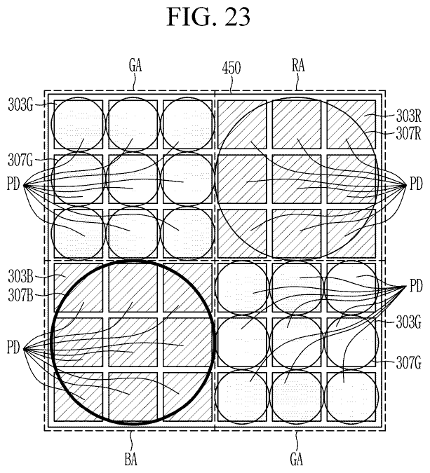

FIG. 23 shows a planar view of an image sensor according to an example embodiment. For example, the planar view of FIG. 23 may be the same region as FIG. 22. Referring to FIG. 23, the image sensor is the same as FIG. 22 except that the thickness of the microlens 307B located in the blue pixel area BA is thicker than the microlenses 307G and the microlens 307R. That is, in FIG. 23, the thickness of the microlens 307R located in the red pixel area RA and the thickness of the microlens 307G located in the green pixel area GA may be the same, and the thickness of the microlens 307B located in the blue pixel area BA may be greater than each of the microlens 307R and the thickness of the microlenses 307G.

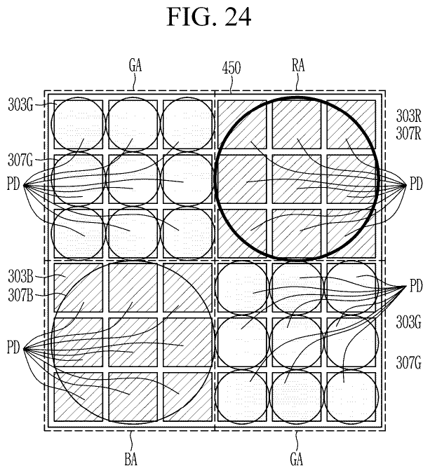

FIG. 24 shows a planar view of an image sensor according to an example embodiment. For example, the planar view of FIG. 24 may be the same region as FIG. 22. Referring to FIG. 24, the image sensor is the same as FIG. 22 except that the thickness of the microlens 307R located in the red pixel area RA is thicker than the microlenses 307G and the microlens 307B. That is, in FIG. 24, the thickness of the microlens 307B located in the blue pixel area BA and the thickness of the microlens 307G located in the green pixel area GA may be the same, and the thickness of the microlens 307R located in the red pixel area RA may be greater than each of the microlens 307B and the thickness of the microlens 307G.

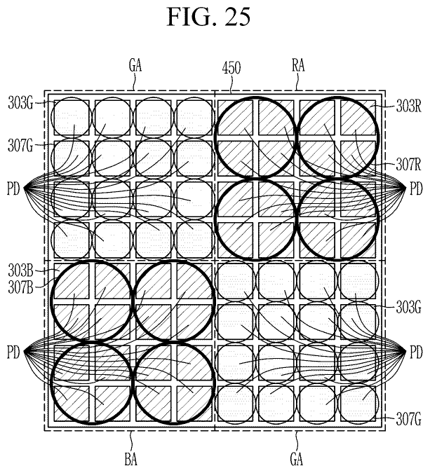

FIG. 25 shows a planar view of an image sensor according to an example embodiment. For example, the planar view of FIG. 25 may be the same region as FIG. 3. Referring to FIG. 25, the image sensor is the same as FIG. 3 except that each pixel area includes sixteen photoelectric conversion elements PD. Referring to FIG. 25, the green pixel area GA may include sixteen microlenses 307G, the red pixel area RA may include four microlenses 307R, and the blue pixel area BA may include four microlenses 307B. The thickness of the microlenses 307G located in the green pixel area GA may be the same. The thickness of the microlenses 307R located in the red pixel area RA may be the same as the thickness of the microlenses 307B located in the blue pixel area BA, and greater than the thickness of the microlenses 307G located in the green pixel areas GA.

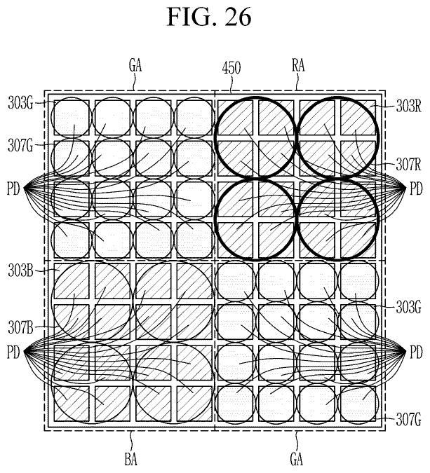

FIG. 26 shows a planar view of an image sensor according to an example embodiment. For example, the planar view of FIG. 26 may be the same region as FIG. 25. Referring to FIG. 26, the image sensor is the same as FIG. 25 except that the thickness of the microlenses 307R located in the red pixel area RA is thicker than the microlenses 307G and the microlenses 307B. That is, in FIG. 26, the microlenses 307B located in the blue pixel area BA and the microlenses 307G located in the green pixel area GA may have the same thickness, and the thickness of the microlenses 307R located in the red pixel area RA may be greater than each of the microlenses 307B and the thickness of the microlenses 307G.

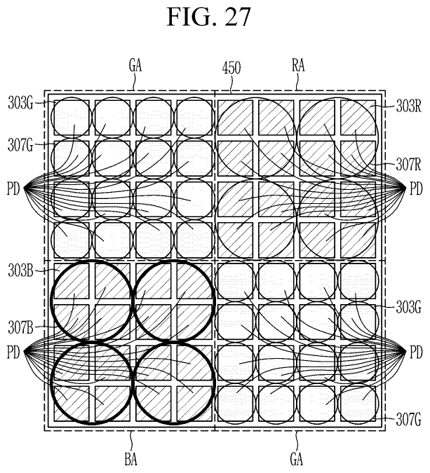

FIG. 27 shows a planar view of an image sensor according to an example embodiment. For example, the planar view of FIG. 27 may be the same region as FIG. 25. Referring to FIG. 27, the image sensor is the same as FIG. 25 except that the thickness of the microlens 307B located in the blue pixel area BA is thick. That is, in FIG. 27, the thickness of the microlens 307R located in the red pixel area RA and the thickness of the microlens 307G located in the green pixel area GA may be the same, and the thickness of the microlens 307B located in the blue pixel area BA may be greater than each of the microlens 307R and the thickness of the microlens 307G.

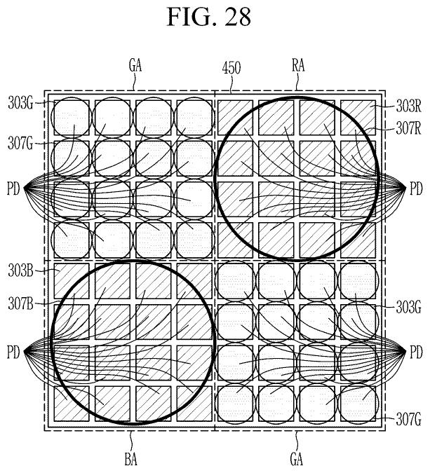

FIG. 28 shows a planar view of an image sensor according to an example embodiment. For example, the planar view of FIG. 28 may be the same region as FIG. 25. Referring to FIG. 28, the image sensor is the same as FIG. 25 except that the red pixel area RA includes one microlens 307R and the blue pixel area BA includes one microlens 307B.

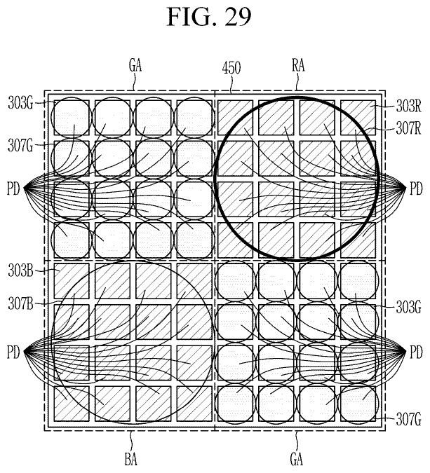

FIG. 29 shows a planar view of an image sensor according to an example embodiment. For example, the planar view of FIG. 29 may be the same region as FIG. 26. Referring to FIG. 29, the image sensor is the same as FIG. 26 except that the red pixel area RA includes one microlens 307R and the blue pixel area BA includes one microlens 307B.

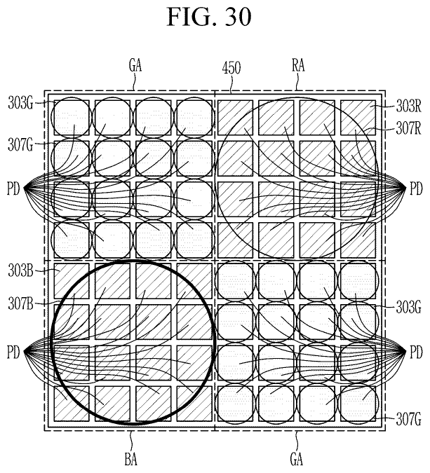

FIG. 30 shows a planar view of an image sensor according to an example embodiment. For example, the planar view of FIG. 30 may be the same region as FIG. 27. Referring to FIG. 30, the image sensor is the same as FIG. 27 except that the red pixel area RA includes one microlens 307R and the blue pixel area BA includes one microlens 307B.

As described above, according to example embodiments, configuration of the quantity of the microlens located in the red pixel area RA, the green pixel area GA, and the blue pixel area BA may vary (as illustrated), but in some example embodiments, the quantity of the microlens located in the red pixel area RA, the green pixel area GA, and the blue pixel area BA may be the same.

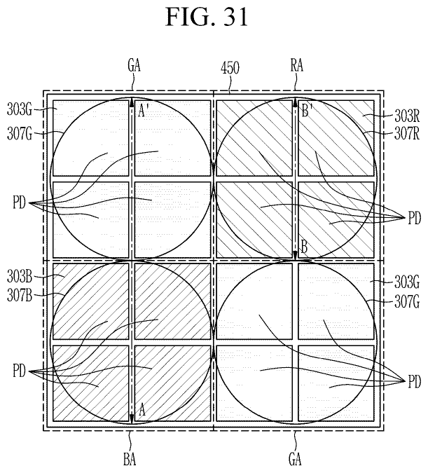

FIG. 31 shows a planar view of an image sensor according to an example embodiment. For example, the planar view of FIG. 31 may be the same region as FIG. 3. Referring to FIG. 31, the image sensor is the same as FIG. 3 except that one microlens 307R is located in the red pixel area RA, one microlens 307G is located in the green pixel area GA, and one microlens 307B is located in the blue pixel area BA. The thicknesses of the respective microlenses 307R, 307G, and 307B may be different.

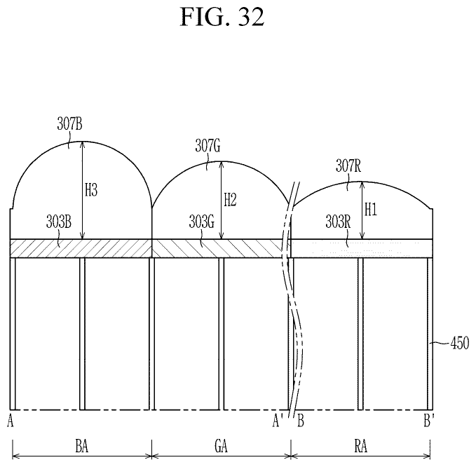

FIG. 32 shows cross-sectional views taken along lines A-A′ and B-B′ of FIG. 31. For better understanding and ease of description, FIG. 32 briefly illustrates only some components. Referring to FIG. 32, the thickness H3 of the microlens 307B located in the blue pixel area BA may be the thickest, and the thickness H1 of the microlens 307R located in the red pixel area RA may be the thinnest. The thickness H2 of the microlens 307G located in the green pixel area GA may be less than the thickness H3 of the microlens 307B located in the blue pixel area BA, and may be greater than the thickness H1 of the microlens 307R located in the red pixel area RA. As such, by forming the thicknesses of the microlenses 307R, 307G, and 307B different in each pixel area, the focal distance for each pixel may be maintained the same.

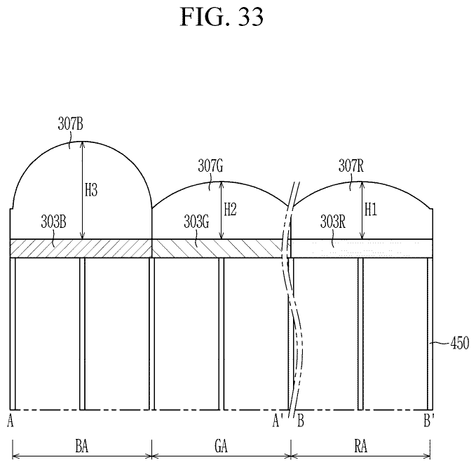

FIG. 33 shows cross-sectional views taken along lines A-A′ and B-B′ of FIG. 31 according to another example embodiment. For better understanding and ease of description, FIG. 33 briefly illustrates only some components. Referring to FIG. 33, the image sensor is the same as FIG. 32 except that the thickness H3 of the microlens 307B located in the lower blue pixel area BA is thickest, and the thickness H1 of the microlens 307R located in the red pixel area RA and the thickness H2 of the microlens 307G located in the green pixel area GA are the same.

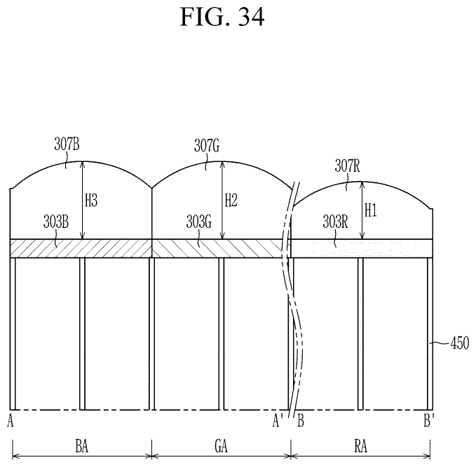

FIG. 34 shows cross-sectional views taken along lines A-A′ and B-B′ of FIG. 31 according to another example embodiment. For better understanding and ease of description, FIG. 34 briefly illustrates only some components. Referring to FIG. 34, the image sensor is the same as FIG. 32 except that the thickness H3 of the microlens 307B located in the blue pixel area BA and the thickness H2 of the microlens 307G located in the green pixel area GA are the same, and the thickness H1 of the microlens 307R located in the red pixel area RA is thin.

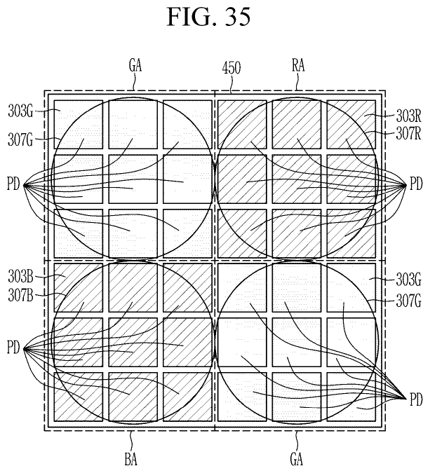

FIG. 35 shows a planar view of an image sensor according to an example embodiment. For example, the planar view of FIG. 35 may be the same region as FIG. 31. Referring to FIG. 35, the image is the same as FIG. 31 except that each of the pixel areas RA, GA, and BA includes nine photoelectric conversion elements PD.

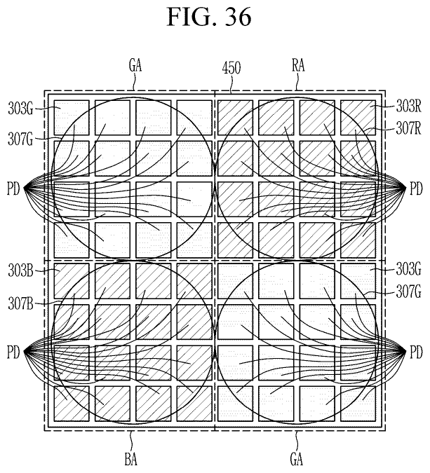

FIG. 36 shows a planar view of an image sensor according to an example embodiment. For example, the planar view of FIG. 36 may be the same region as FIG. 31. Referring to FIG. 36, the image sensor is the same as FIG. 31 except that each of the pixel areas RA, GA, and BA includes sixteen photoelectric conversion elements PD.

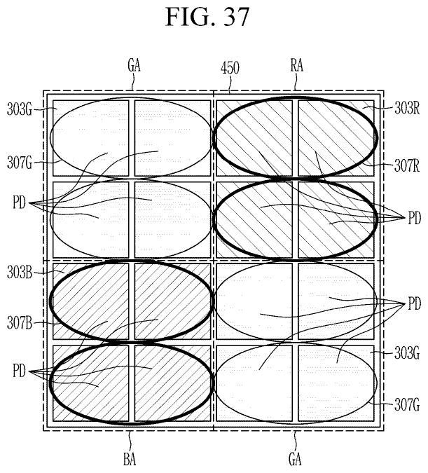

FIG. 37 shows a planar view of an image sensor according to an example embodiment. For example, the planar view of FIG. 37 may be the same region as FIG. 31. FIG. 37 is the same as FIG. 31 except that two microlenses 307R, are located in the pixel area RA, two microlenses 307G are located in the pixel area GA, and two microlenses 307B are located in the pixel area BA. Referring to FIG. 37, the thickness of the microlenses 307R located in the red pixel area RA and the thickness of the microlenses 307B located in the blue pixel area BA may be greater than the thickness of the microlenses 307G located in the green pixel area GA.

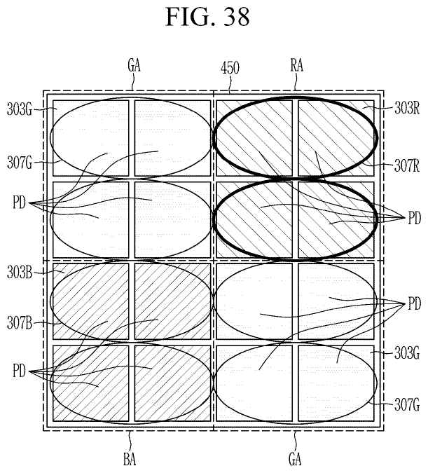

FIG. 38 shows a planar view of an image sensor according to an example embodiment. For example, the planar view of FIG. 38 may be the same region as FIG. 37. Referring to FIG. 38, the image sensor is the same as FIG. 37 except that the thickness of the microlenses 307R located in the red pixel area RA is thicker than the microlenses 307G and the microlenses 307B. That is, in FIG. 37, the thickness of the microlens 307B located in the blue pixel area BA and the thickness of the microlens 307G located in the green pixel area GA may be the same, and the thickness of the microlens 307R located in the red pixel area RA may be greater than each of the microlens 307B and the thickness of the microlens 307G.

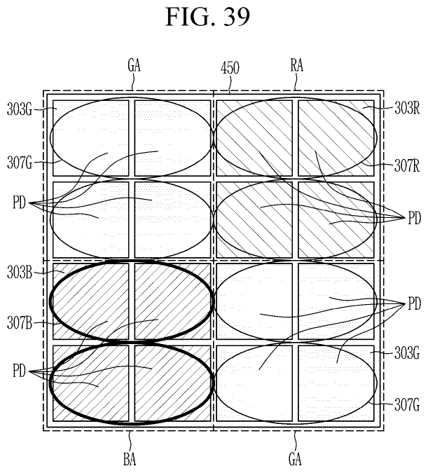

FIG. 39 shows a planar view of an image sensor according to an example embodiment. For example, the planar view of FIG. 39 may be the same region as FIG. 37. Referring to FIG. 39, the image sensor is the same as FIG. 37 except that the thickness of the microlens 307B located in the blue pixel area BA is thick. That is, in the FIG. 39, the thickness of the microlens 307R located in the red pixel area RA and the thickness of the microlens 307G located in the green pixel area GA may be the same, and the thickness of the microlens 307B located in the blue pixel area BA may be greater than each of the microlens 307R and the thickness of the microlens 307G.

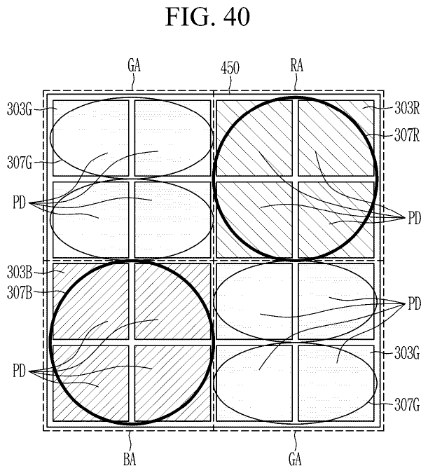

FIG. 40 shows a planar view of an image sensor according to an example embodiment. For example, the planar view of FIG. 40 may be the same region as FIG. 37. Referring to FIG. 40, the image sensor is the same as FIG. 37 except that the red pixel area RA includes one microlens 307R and the blue pixel area BA includes one microlens 307B.

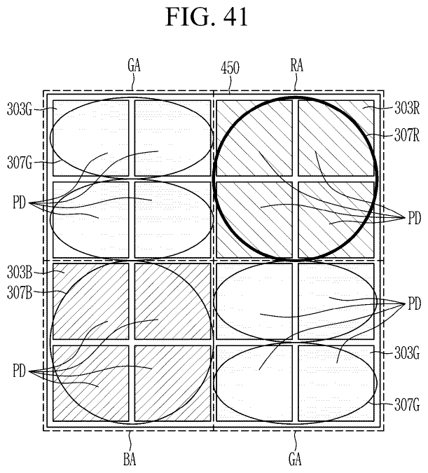

FIG. 41 shows a planar view of an image sensor according to an example embodiment. For example, the planar view of FIG. 41 may be the same region as FIG. 38. Referring to FIG. 41, the image sensor is the same as FIG. 38 except that the red pixel area RA includes one microlens 307R and the blue pixel area BA includes one microlens 307B.

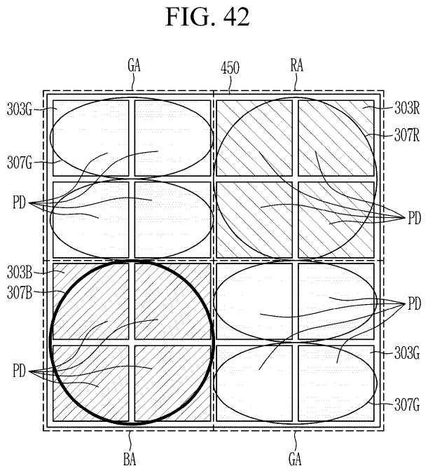

FIG. 42 shows a planar view of an image sensor according to an example embodiment. For example, the planar view of FIG. 42 may be the same region as FIG. 39. Referring to FIG. 42, the image sensor is the same as FIG. 39 except that the red pixel area RA includes one microlens 307R and the blue pixel area BA includes one microlens 307B.

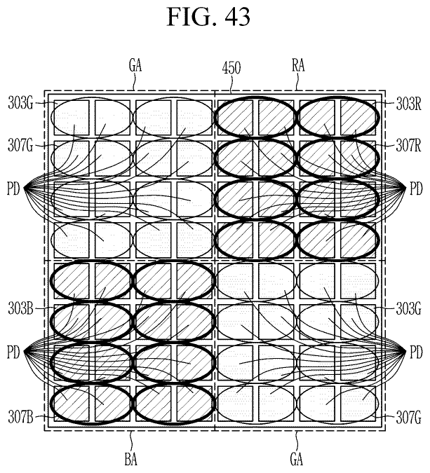

FIG. 43 shows a planar view of an image sensor according to an example embodiment. For example, the planar view of FIG. 43 may be the same region as FIG. 37. Referring to FIG. 43, the image sensor is the same as FIG. 37 except that the pixel areas RA, GA, and BA include sixteen photoelectric conversion elements PD, respectively. Referring to FIG. 43, the green pixel area GA may include sixteen photoelectric conversion elements PD, and may include eight microlenses 307G. The red pixel area RA and the blue pixel area BA may also include sixteen photoelectric conversion elements PD. The red pixel area RA may include eight microlenses 307R. The blue pixel area BA may include eight microlenses 307B. Referring to FIG. 43, the thickness of the microlenses 307R located in the red pixel area RA and the thickness of the microlenses 307B located in the blue pixel area BA may be greater than the thickness of the microlenses 307G located in the green pixel area GA.

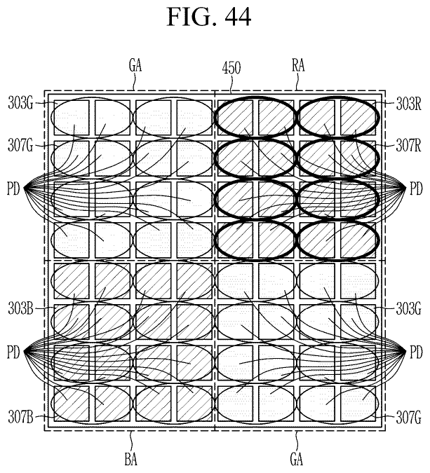

FIG. 44 shows a planar view of an image sensor according to an example embodiment. For example, the planar view of FIG. 44 may be the same region as FIG. 38. Referring to FIG. 44, the image sensor is the same as FIG. 38 except that the pixel areas RA, GA, and BA include sixteen photoelectric conversion elements PD, respectively. That is, in FIG. 44, the microlenses 307B located in the blue pixel area BA and the thickness of the microlenses 307G located in the green pixel area GA may be the same, and the thickness of the microlenses 307R located in the red pixel area RA may be greater than each of the microlenses 307B and the thickness of the microlenses 307G.

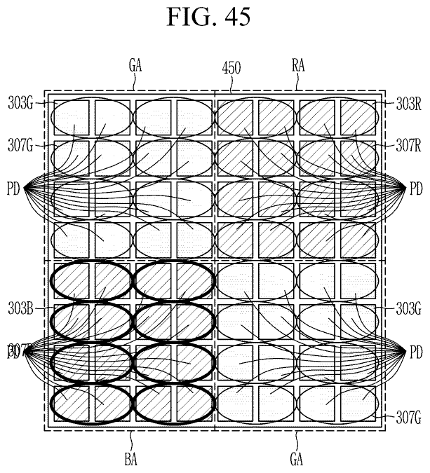

FIG. 45 shows a planar view of an image sensor according to an example embodiment. For example, the planar view of FIG. 45 may be the same region as FIG. 39. Referring to FIG. 45, the image sensor is the same as FIG. 39 except that the pixel areas RA, GA, and BA include sixteen photoelectric conversion elements PD, respectively. That is, in FIG. 45, the thickness of the microlenses 307R located in the red pixel area RA and the thickness of the microlenses 307G located in the green pixel area GA may be the same, and the thickness of the microlenses 307B located in the blue pixel area BA may be greater than each of the microlenses 307R and the thickness of the microlenses 307G.

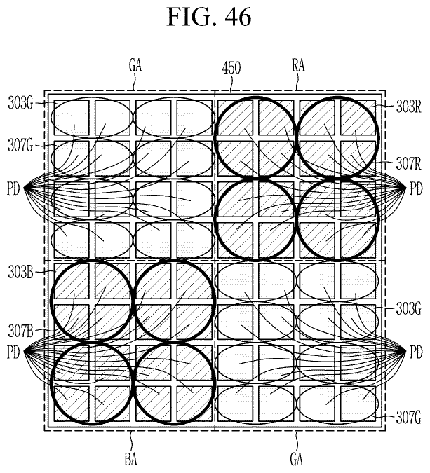

FIG. 46 shows a planar view of an image sensor according to an example embodiment. For example, the planar view of FIG. 46 may be the same region as FIG. 43. Referring to FIG. 46, the image sensor according is the same as FIG. 43 except that the red pixel area RA includes four microlenses 307R, and the blue pixel area BA includes four microlenses 307B. Referring to FIG. 46, the thickness of the microlenses 307R located in the red pixel area RA and the thickness of the microlenses 307B located in the blue pixel area BA may be greater than the thickness of the microlenses 307G located in the green pixel area GA.

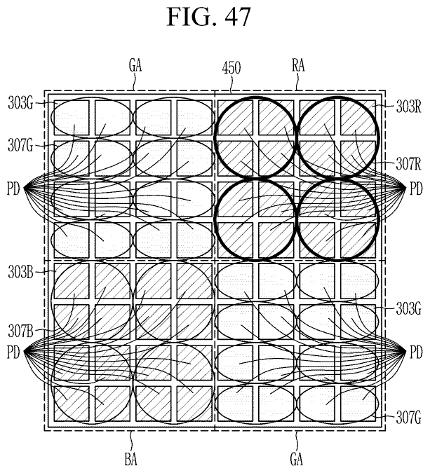

FIG. 47 shows a planar view of an image sensor according to an example embodiment. For example, the planar view of FIG. 47 may be the same region as FIG. 44. Referring to FIG. 47, the image sensor is the same as FIG. 44 except that the red pixel area RA includes the four microlenses 307R, and the blue pixel area BA includes four microlenses 307B. That is, in FIG. 47, the microlenses 307B located in the blue pixel area BA and the thickness of the microlenses 307G located in the green pixel area GA may be the same, and the thickness of the microlenses 307R located in the red pixel area RA may be greater than each of the microlenses 307B and the thickness of the microlenses 307G.

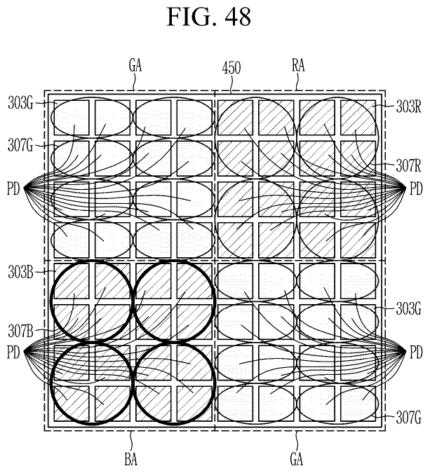

FIG. 48 shows a planar view of an image sensor according to an example embodiment. For example, the planar view of FIG. 48 may be the same region as FIG. 45. Referring to FIG. 48, the image sensor is the same as FIG. 45 except that the red pixel area RA includes the four microlenses 307R, and the blue pixel area BA includes four microlenses 307B. That is, in FIG. 48, the microlenses 307R located in the red pixel area RA and the thickness of the microlenses 307G located in the green pixel area GA may be the same, and the thickness of the microlenses 307B located in the blue pixel area BA may be greater than each of the microlenses 307R and the thickness of the microlenses 307G.

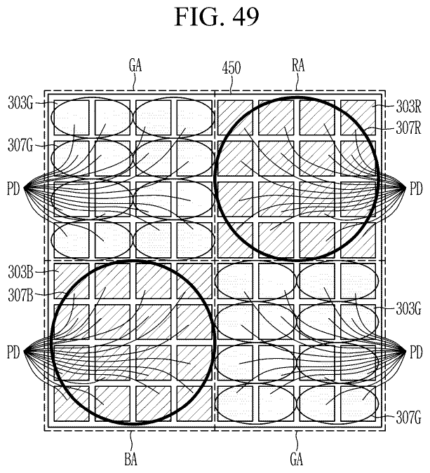

FIG. 49 shows a planar view of an image sensor according to an example embodiment. For example, the planar view of FIG. 49 may be the same region as FIG. 46. Referring to FIG. 49, the image sensor is the same as FIG. 46 except that the red pixel area RA includes one microlens 307R, and the blue pixel area BA includes one microlens 307B. Referring to FIG. 49, the thickness of the microlens 307R located in the red pixel area RA and the thickness of the microlens 307B located in the blue pixel area BA may be greater than the thickness of the microlenses 307G located in the green pixel area GA.

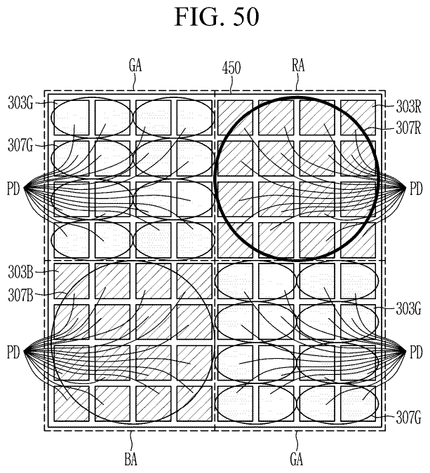

FIG. 50 shows a planar view of an image sensor according to an example embodiment. For example, the planar view of FIG. 50 may be the same region as FIG. 47. Referring to FIG. 50, the image sensor is the same as FIG. 47 except that the red pixel area RA includes one microlens 307R, and the blue pixel area BA includes one microlens 307B. That is, in FIG. 50, the thickness of the microlens 307B located in the blue pixel area BA and the thickness of the microlens 307G located in the green pixel area GA may be the same, and the thickness of the microlens 307R located in the red pixel area RA may be greater than each of the microlens 307B and the thickness of the microlenses 307G.

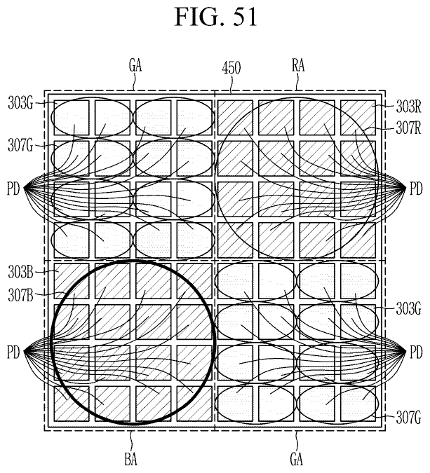

FIG. 51 shows a planar view of an image sensor according to an example embodiment. For example, the planar view of FIG. 51 may be the same region as FIG. 48. Referring to FIG. 51, the image sensor is the same as FIG. 45 except that the red pixel area RA includes one microlens 307R, and the blue pixel area BA includes one microlens 307B. That is, in FIG. 51, the thickness of the microlens 307R located in the red pixel area RA and the thickness of the microlens 307G located in the green pixel area GA may be the same, and the thickness of the microlens 307B located in the blue pixel area BA may be greater than each of the microlens 307R and the thickness of the microlenses 307G.

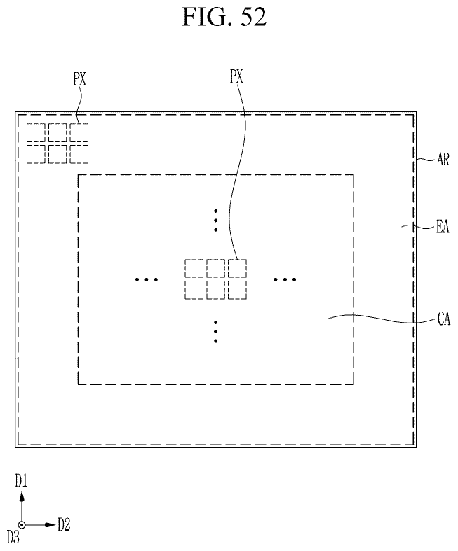

In an image sensor according to example embodiments, the arrangement and shape of the microlenses may be different depending on locations within the image sensor. FIG. 52 schematically shows a pixel array region AR. In FIG. 52, a central area CA and an outer area EA are illustrated separately. As shown in FIG. 52, the outer area EA may surround the central area CA. The pixels described above may be pixels positioned in the central area CA, and pixels positioned in the outer area EA will be described below.

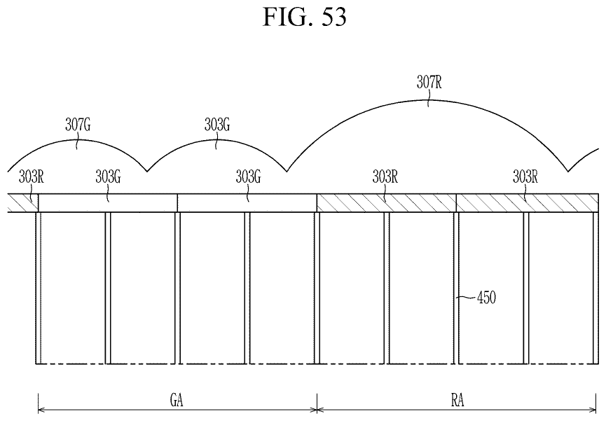

FIG. 53 schematically shows a cross-section for a pixel located on the outer area EA according to an example embodiment. Referring to FIG. 53, in the image sensor according to an example embodiment, centers of the microlenses 307G and 307B may not coincide with centers of the respective photoelectric conversion elements PD. That is, a thickest portion of the microlens may not coincide with (i.e., may be offset from) a central portion of the photoelectric conversion element PD. This is to correct light coming in at an oblique angle from an outside of the image sensor so that the light coming in at the oblique angle may be located at the center of each pixel. Even in the case where the centers of the microlenses 307G and 307B do not coincide with the centers of the respective photoelectric conversion elements PD, it may be included in the scope of overlap of this specification.

The degree to which the microlens 307 is shifted may increase from the central area CA to the outer area EA. This is to compensate for the fact that the light is incident more obliquely as it goes toward the outer area.

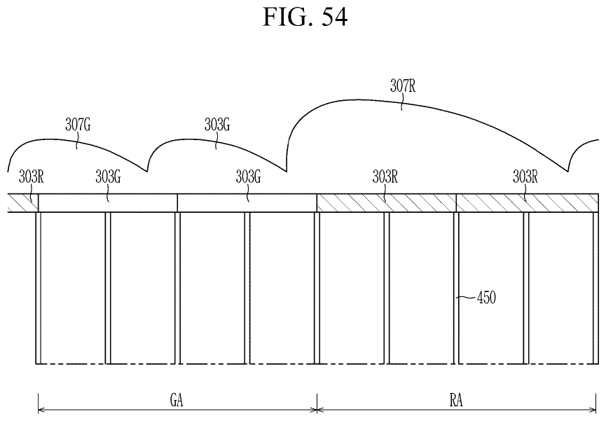

In addition, in an example embodiment, the shape of the microlens 307 located in the outer area EA may be different. FIG. 54 shows the same cross-section as FIG. 53 for another example embodiment. Referring to FIG. 54, the microlens 307 may have a shape that is more convex on one side rather than having a symmetrical shape on both sides. This is a structure in which the microlens 307 in a direction in which the light is majorly incident is formed more convexly, such that the light may be well collected. Even in the case of FIG. 53, the degree to which the microlens 307 is convex on one side may increase, from the central area CA toward the outer area EA. This is to compensate for the fact that the light is incident more obliquely as it goes toward the outer area. As described above, the microlens 307 of this shape may be formed by appropriately using the first photoresist layer PR1 and the second photoresist layer PR2.

While aspects of example embodiments have been particularly shown and described, it will be understood that various changes in form and details may be made therein without departing from the spirit and scope of the following claims.

What is claimed is:

1. An image sensor comprising
a first substrate;
a first color filter and a first microlens provided on a plurality of first photoelectric conversion elements in a first region of the first substrate;
a second color filter and a second microlens provided on a plurality of second photoelectric conversion elements in a second region of the first substrate; and
a third color filter and a third microlens provided on a plurality of third photoelectric conversion elements in a third region of the first substrate,
wherein the first microlens overlaps with a first photoelectric conversion element among the plurality of first photoelectric conversion elements,
wherein the second microlens overlaps with at least four of the plurality of second photoelectric conversion elements, and
wherein a thickness of the second microlens is greater than a thickness of the first microlens.

2. The image sensor of claim 1, wherein the third microlens overlaps with at least four of the plurality of third photoelectric conversion elements, and
wherein a thickness of the third microlens is greater than the thickness of the first microlens.

3. The image sensor of claim 1, wherein the first color filter is a green color filter, and
wherein the second color filter is a red color filter or a blue color filter.

4. The image sensor of claim 1, wherein the first to third plurality of photoelectric conversion elements comprise four photoelectric conversion elements, respectively, and
wherein the second microlens overlaps with the four photoelectric conversion elements of the plurality of second photoelectric conversion elements, and
wherein the third microlens overlaps with the four photoelectric conversion elements of the plurality of third photoelectric conversion elements.

5. The image sensor of claim 1, wherein the first to the plurality of third photoelectric conversion elements comprise nine photoelectric conversion elements, respectively, and
wherein the second microlens overlaps the nine photoelectric conversion elements of the plurality of second photoelectric conversion elements, and
wherein the third microlens overlaps the nine photoelectric conversion elements of the plurality of third photoelectric conversion elements.

6. The image sensor of claim 1, wherein the first to third plurality of photoelectric conversion elements comprise sixteen photoelectric conversion elements, respectively,
wherein the second microlens overlaps with four photoelectric conversion elements of the plurality of second photoelectric conversion elements, and
wherein the third microlens overlaps with four photoelectric conversion elements of the plurality of third photoelectric conversion elements.

7. The image sensor of claim 1, wherein the first to third plurality of photoelectric conversion elements comprise sixteen photoelectric conversion elements, respectively, and
wherein the second microlens overlaps with the sixteen photoelectric conversion elements of the plurality of second photoelectric conversion elements, and
wherein the third microlens overlaps with the sixteen photoelectric conversion elements of the plurality of third photoelectric conversion elements.

8. An image sensor comprising:
a first substrate;
a first color filter and a first microlens provided on a plurality of first photoelectric conversion elements in a first region of the first substrate;
a second color filter and a second microlens provided on a plurality of second photoelectric conversion elements in a second region of the first substrate; and
a third color filter and a third microlens provided on a plurality of third photoelectric conversion elements in a third region of the first substrate,
wherein a first quantity of the plurality of first photoelectric conversion elements overlapping with the first microlens, a second quantity of the plurality of second photoelectric conversion elements overlapping with the second microlens, and a third quantity of the plurality of third photoelectric conversion elements overlapping with the third microlens are the same, and
wherein a thickness of the first microlens and a thickness of the third microlens are different.

9. The image sensor of claim 8, wherein a thickness of the second microlens and the thickness of the first microlens are different, and
wherein the thickness of the second microlens and the thickness of the third microlens are different.

10. The image sensor of claim 8, wherein a thickness of the second microlens corresponds the thickness of the third microlens.

11. The image sensor of claim 8, wherein the second color filter is a green color filter, and
wherein the first color filter is a red color filter or a blue color filter.

12. The image sensor of claim 8, wherein each of the one first microlens, the second microlens, and the third microlens, comprises 2, 4, 9, or 16 microlenses.

13. An image sensor comprising:
a first substrate;
a first color filter and a first microlens provided on a plurality of first photoelectric conversion elements in a first region of the first substrate;
a second color filter and a second microlens provided on a plurality of second photoelectric conversion elements in a second region of the first substrate; and
a third color filter and a third microlens provided on a plurality of third photoelectric conversion elements in a third region of the first substrate,
wherein a quantity of the plurality of second photoelectric conversion elements is at least two times greater than a quantity of the plurality of first photoelectric conversion elements, and
wherein a thickness of the second microlens is greater than a thickness of the first microlens.

14. The image sensor of claim 13, wherein a quantity of the plurality of third photoelectric conversion elements is at least two times greater than the quantity of the plurality of first photoelectric conversion elements, and
wherein a thickness of the third microlens is greater than the thickness of the first microlens.

15. The image sensor of claim 13, wherein the first color filter is a green color filter, and
wherein the second color filter is a red color filter or a blue color filter.

16. The image sensor of claim 13, wherein the plurality of first photoelectric conversion elements, the plurality of second photoelectric conversion elements and the plurality of third photoelectric conversion elements comprise four photoelectric conversion elements, respectively.

17. The image sensor of claim 16, wherein the plurality of first photoelectric conversion elements comprises two photoelectric conversion elements, and
wherein the plurality of second photoelectric conversion elements comprises four photoelectric conversion elements.

18. The image sensor of claim 13, wherein the plurality of first photoelectric conversion elements, the plurality of second photoelectric conversion elements and the plurality of third photoelectric conversion elements comprise sixteen photoelectric conversion elements, respectively.

19. The image sensor of claim 18, wherein the plurality of first photoelectric conversion elements comprises two photoelectric conversion elements, and
wherein the plurality of second photoelectric conversion elements comprises four photoelectric conversion elements.

20. The image sensor of claim 18, wherein the plurality of first photoelectric conversion elements comprises two photoelectric conversion elements, and
wherein the plurality of second photoelectric conversion elements comprises sixteen photoelectric conversion elements.
